(19) United States
(12) Patent Application Publication
(10) Pub. No.: US 2008/0237724 A1
(43) Pub. Date: Oct. 2, 2008

(54) Semiconductor thin film manufacturing method, semiconductor thin film and thin film transistor

(75) Inventor: Mitsuru NAKATA, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC LCD Technologies, Ltd., Kawasaki (JP)

(21) Appl. No.: 12/076,533

(22) Filed: Mar. 19, 2008

(30) Foreign Application Priority Data
Mar. 29, 2007 (JP) 2007-086193

(51) Int. Cl. H01L 29/786; H01L 21/20; G03F 1/00

(52) U.S. Cl. 257/368; 438/479; 430/5; 257/E21.09; 257/E29.273

(57) ABSTRACT

To provide a semiconductor thin film on which crystal grains with large diameters are formed over a wide range. A beam pattern including a plurality of recessed patterns is scan-irradiated to amorphous silicon in a first scanning direction (first crystallization step). Then, a beam pattern is scan-irradiated in a second scanning direction that is different from the first scanning direction by 90 degrees (second crystallization step). As a result, by having band-shape crystal grains formed in the first crystallization step as seeds, the crystal grain diameters thereof are expanded in the second scanning direction. That is, it is possible to obtain new band-shape crystal grains with the expanded grain diameters.

### CROSS-REFERENCE TO RELATED APPLICATION

This application is based upon and claims the benefit of priority from Japanese patent application No. 2007-086193, filed on Mar. 29, 2007, the disclosure of which is incorporated herein in its entirety by reference.

### BACKGROUND OF THE INVENTION

1. Field of the Invention

The present invention relates to a semiconductor thin film manufacturing method which controls crystal grain boundaries, and to a semiconductor thin film as well as a thin film transistor obtained by the manufacturing method.

2. Description of the Related Art

As switching elements for configuring pixels in a liquid crystal display device, thin film transistors (referred to as “TFT” hereinafter) formed on a glass substrate are utilized. Recently, in addition to realization of high-definition liquid crystal display devices, there has been an increasing demand for improving the action speed of TFT in order to achieve system-on-glass. Therefore, a high-quality laser anneal polycrystalline silicon TFT forming technique has drawn an attention.

The TFT described above is normally fabricated in the manner as shown in FIG. 13. For example, as shown in FIG. 13A, an amorphous silicon 1201 is formed on an insulating film 1202 that is formed on a surface of a glass substrate 1203. Subsequently, as shown in FIG. 13B, a laser beam 1204 is irradiated onto the surface of the amorphous silicon 1201 to form a polycrystalline silicon 1201a. Then, as shown in FIG. 13C, a source region 1207, a drain region 1209, and a channel (active layer) 1208 sandwiched between the source region 1207 and the drain region 1209 are formed in the obtained polycrystalline silicon 1201a, and a gate insulating film 1212 and a gate electrode 1206 are formed thereon. After forming an interlayer insulating film 1211 to cover the gate electrode 1206 and the gate insulating film 1212, a contact hole is formed through the interlayer insulating film 1211 and the gate insulating film 1212. Then, a source electrode 1205 connecting to the contact hole of the source region 1207 and a drain electrode 1210 connecting to the contact hole of the drain region 1209 are formed respectively on the interlayer insulating film 1211, thereby completing a TFT.

Recently, there has been more and more demand for improving the action speed of polycrystalline TFT. The action speed becomes higher as the mobility of carries (electrons or positive holes) within a channel becomes significant. However, if there are a large number of crystal grain boundaries within the channel, the carrier mobility becomes deteriorated. For this, there is disclosed a technique that improves the carrier mobility by decreasing the number of crystal grain boundaries within the channel through controlling the crystal growth at the time of performing laser annealing, as depicted in the followings.

“Sequential lateral solidification of thin silicon films on SiO₂”, Robert S. Sposili and James S. Im, Appl. Phys. Lett. 69 (19) 1966 pp. 2864-2866 (Non-patent Document 1) discloses a technique which scans a thin-linear beam as a beam pattern to form huge crystal grains in the scanning direction. This technique will be described hereinafter.

First, as shown in FIG. 14A, a pulse laser beam is shaped into a thin-linear beam 1302 by a prescribed mask, and the shaped thin-linear beam 1302 is irradiated to the amorphous silicon 1301 on the substrate while being scanned along the substrate. With this, the amorphous silicon 1301 is heated (annealed) successively.

As shown in FIG. 14B, by irradiating the thin-linear beam 1302 for the first time, crystallization of the melted amorphous silicon film proceeds in the following manner. First, each of the crystals grows towards the center part of the melted area starting from the end point of the thin-linear beam in the scanning direction (beam width direction), which forms an interface of solid and liquid phases between the neighboring non-melted regions. As a result, the solidified part becomes the crystallized polycrystalline silicon 1301a. Further, each crystal comes into collision in the vicinity of the center part and stops its growth, and the crystal grain boundary is formed in this part. A large number of crystal grain boundaries along the scanning direction are generated in a direction (beam length direction) that is perpendicular to the scanning direction.

Subsequently, as shown in FIG. 14C, a second irradiation of the thin-linear beam 1302a is performed. The scanning amount of the thin-linear beam 1302a in the second irradiation is equal to or less than the diameter of the crystal grains that are crystallized along the scanning direction of the thin-linear beam 1302a of the first irradiation.

Subsequently, as shown in FIG. 14D, the crystal grains grown by the first irradiation are used as seeds to perform crystal growth in accordance with the second irradiation of the thin-linear beam 1302a.

By repeating melting and crystallization of the amorphous silicon 1301 through successively scanning the laser irradiation area, crystal grains 1303 extending in the scanning direction can be formed as shown in FIG. 14E. The boundaries between each of the neighboring crystal grains 1303 are crystal grain boundaries 1304.

Japanese Unexamined Patent Publication H11-064883 (Patent Document 1) discloses a technique which uses a light-shielding mask including a light shielding part 1402 and a zigzag-patterned transmitting part 1401 shown in FIG. 15A to let a beam transmits through the transmitting part 1401 so as to shape the beam into a zigzag beam pattern for executing scan-irradiation. With this technique, the crystals are grown not only in the scanning direction but also in the direction that is perpendicular to the scanning direction by having the vertexes of the beam pattern as starting points. As a result, as shown in FIG. 15B, it is reported that position-controlled crystal grains 1502 can be formed by corresponding to the cycle of the zigzag pattern. In FIG. 15B, reference numeral 1501 indicates a highly-dense grain boundary region, and 1503 indicates a crystal grain boundary.

Japanese Unexamined Patent Publication 2002-057105 (Patent Document 2) discloses a technique which executes a first irradiation for forming crystal grains grown in a scanning direction by a thin-linear beam or a zigzag-patterned beam, and then performs scan-irradiation (second irradiation) by a thin-linear beam in a direction that is perpendicular to the scanning direction of the first irradiation, so that crystal grains with a large grain diameter can be formed.

Japanese Unexamined Patent Publication 2006-245520 (Patent Document 3) discloses a technique for performing scan-irradiation of a beam pattern shaped in a recessed form. With this technique, the crystals are grown not only in the scanning direction but also in the direction that is perpendicular to the scanning direction by having the vertexes of the beam pattern as starting points. Thus, band-shape crystal grains can be formed at desired positions. Further, by performing scan-irradiation of the beam pattern including a plurality of recessed patterns, it becomes possible to form the band-shape crystal grains that are lined in the direction perpendicular to the scanning direction.

In a case of using a laser annealing method according to Non-patent Document 1, it is possible to extend the crystal grains in the scanning direction (beam width direction) of the laser beam. However, there is no temperature gradient in a direction (beam length direction) which is orthogonal to the scanning direction of the laser beam, so that crystal grain boundaries are generated randomly in the beam length direction. Therefore, there are such issues generated that the growth of the crystal grains may be interrupted and the grain diameter in the beam length direction becomes as short as about 1 μm. As a result, in a case of fabricating TFT by providing a channel in such a manner that the carriers move in parallel to the scanning direction, the crystal grain boundaries are generated within the channel since the crystal grain boundary positions are not controlled. This results in causing such issues that the carrier mobility is deteriorated, and the mobility and threshold voltage are fluctuated greatly. Further, in a case of fabricating TFT by providing a channel in such a manner that the carriers move in a direction perpendicular to the scanning direction, the crystal grain boundaries are generated within the channel to block the move of the carries since the crystal grain boundary positions are not controlled. This results in causing such issues that the carrier mobility is deteriorated, and the mobility and a threshold voltage are fluctuated greatly.

Further, protrusions are generated along the crystal grain boundaries for every scanning step. Since the crystal grain boundaries in the beam width direction are generated randomly, layout of the protrusions in the beam width direction becomes random. In a TFT that contains the protrusions in the channel, the electric fields at the time of action are concentrated on the protrusions, thereby causing fluctuation in the threshold voltage. That is, in the TFT fabricated by the first related technique with which the layout and the number of the protrusions within the channel become random, there is a significant variation generated in the threshold voltage.

In the laser annealing method using a light-shielding mask according to Patent Document 1, the beam pattern on the light-shielding mask is normally in a rectangular shape (laser irradiation area 1403) that is shown in FIG. 15A. Thus, when a laser is irradiated through a mask of a zigzag pattern used in a second related technique, the transmittance of the laser beam is decreased compared to a case of forming a thin-linear beam that is used in the first related technique. As a result, the beam length irradiated on the substrate becomes short. Thus, the polysilicon crystal region obtained by one-time scan-irradiation becomes narrow, so that the time required for processing the substrate becomes extended.

Further, in the obtained crystals, highly-dense grain boundary regions 1501 are generated over a wide range as shown in FIG. 15B at the irradiation start positions and the irradiation end positions. Furthermore, to form a complicated zigzag pattern in a mask forming process increases the cost compared to a case of using a linear pattern. Moreover, it is necessary to provide an optical system requiring high resolution to the laser annealing device in order to form a zigzag pattern beam.

With a method according to Patent Document 2 which expands the diameter of crystal grains by performing scan-irradiation twice, when the first irradiation beam pattern is a thin-linear beam, the crystal grain boundaries are not controlled in the direction that is perpendicular to the first irradiation. Therefore, even though the size of the crystal grains can be expanded by the second irradiation, the positions of the crystal grains cannot be controlled.

Further, when the beam pattern of the first irradiation is a zigzag pattern, there are such issues that the time for processing the substrate becomes extended, the manufacturing cost is high, and it is necessary to provide an optical system requiring high resolution to the laser annealing device, as have been described as the issues of Patent Document 2. Furthermore, since there is a single zigzag pattern, it is necessary to adjust the position of a side of the second irradiation beam pattern on the opposite side of the scanning direction to be inside the single crystal grain formed by the first irradiation. Therefore, it is necessary to provide a sophisticated alignment mechanism to the laser annealing device. Further, since different beam patterns are used for the first irradiation and the second irradiation, it is necessary to change the mask or the device, thereby extending the processing time.

With the scan-irradiation of the beam in a recessed pattern as depicted in Patent Document 3, the width of the band-shape crystal grains is limited. Therefore, for fabricating an excellent TFT that has no crystal grain boundary in the channel, there are such issues that the channel size is limited, it is necessary to provide a sophisticated alignment mechanism to the laser annealing device or an exposure device, and it is necessary to provide a high-resolution exposure device. Furthermore, since the azimuth of the crystals cannot be controlled, there is a significant variation generated in the TFT characteristic within the substrate plane.

### SUMMARY OF THE INVENTION

An exemplary object of the present invention therefore is to provide a semiconductor thin film manufacturing method that is capable of forming crystal grains with a large grain diameter over a wide range and to provide a semiconductor thin film as well as TFT obtained by the manufacturing method.

In order to achieve the foregoing exemplary object, a semiconductor thin film manufacturing method according to an exemplary aspect of the invention is a semiconductor thin film manufacturing method which crystallizes a semiconductor thin film on a substrate by irradiation of a laser beam. The method includes:

shaping an irradiation pattern of the laser beam into a beam pattern including a recessed pattern on one side by letting the laser beam through a mask;

growing crystal grains by having the recessed pattern as a center through scanning the beam pattern in a first scanning direction to grow band-shape crystal grains; and

expanding a crystal grain diameter of the semiconductor thin film by using the band-shape crystal grains as seeds through scanning a beam pattern in a second scanning direction that is different from the first scanning direction.

A mask used in the semiconductor thin film manufacturing method of the present invention is a mask for shaping a beam for growing a semiconductor thin film, which includes, in a transmitting part of the mask, a recessed pattern for shaping the beam into a beam pattern for growing crystal grains of the semiconductor thin film.

The present invention includes: a first crystallization step which scan-irradiates a beam pattern (having at least a part of a side opposite from the first scanning direction has a recessed pattern) to a semiconductor thin film in a first scanning direction; and a second crystallization step which scan-irradiates a beam pattern to the semiconductor thin film in a second scanning direction that is different from the first scanning direction. Thus, the crystal grain diameters can be grown still larger in the second scanning direction by using the band-shape crystal grains formed by the first crystallization step as the seeds.

That is, as an exemplary advantage according to the invention, it becomes possible to expand the crystal grain diameter on the semiconductor thin film and to manufacture the semiconductor thin film on which the azimuth of the crystal grains is controlled. Further, since the transmittance of the laser beam is larger than that of a zigzag pattern, the beam length can be made longer. Thus, the laser annealing processing time per substrate can be shortened by expanding the area of one-time scan-irradiation. Furthermore, by shortening the beam recessed part width of the recessed pattern, it is possible to narrow highly-dense grain boundary regions that are generated at the beam irradiation start positions compared to the case of the zigzag pattern. Further, the front half end of the beam is a straight line extending in a direction perpendicular to the scanning direction. Thus, the highly-dense grain boundary regions generated at the beam irradiation end positions are about the size of the crystal growth distance obtained by one-time irradiation, which is narrower than the case of the zigzag pattern. Further, the mask manufacturing steps for the recessed pattern are simpler compared to that of the zigzag pattern, so that the manufacturing cost can be reduced. Furthermore, unlike the case of forming the zigzag pattern, it is unnecessary for the optical system used for laser annealing to have high resolution in the case of forming the recessed pattern. Moreover, there is only a single mask used therein, so that the processing time can be shortened. In addition, it is possible to improve the carrier mobility as well as variations in the mobility and the threshold voltage of TFTs that are fabricated by using the semiconductor thin film obtained thereby.

Further, by improving the transmittance of the optical system, it is possible to shorten the laser annealing processing time, to narrow the highly-dense grain boundary regions generated at the irradiation start positions and irradiation ending positions, to reduce the mask manufacturing cost, and to have an optical system with lower resolution for the laser annealing, compared to the case of using the zigzag pattern. Furthermore, the processing steps can be shortened. Moreover, it is possible to improve the operation speed as well as variations in the mobility and the threshold voltage of TFTs that are fabricated by using the semiconductor thin film obtained thereby.

### BRIEF DESCRIPTION OF THE DRAWINGS

FIG. 1A-FIG. 1D illustrate plan views showing an exemplary embodiment of a semiconductor thin film manufacturing method according to the present invention, and the process thereof proceeds in order of FIG. 1A-FIG. 1D;

FIG. 2 is an illustration showing a laser annealing device according to the present invention;

FIG. 3A is a plan view showing a mask of the laser annealing device according to the present invention, and FIG. 3B is a plan view showing a beam pattern according to the present invention;

FIG. 4A-FIG. 4C illustrate plan views showing laser annealing process according to the present invention, and the process is executed in order of FIG. 4A-FIG. 4C;

FIG. 5A is a plan view showing a mask of the laser annealing device according to the present invention, and FIG. 5B is a plan view showing a beam pattern according to the present invention;

FIG. 6A is an illustration showing an SEM image of a polycrystalline film surface that is formed by a first crystallization step according to EXAMPLE 1, and FIG. 6B is an illustration showing an SEM image of a polycrystalline film surface that is formed by a second crystallization step according to EXAMPLE 1;

FIG. 7 is a conceptual diagram showing the semiconductor thin film manufacturing method according to EXAMPLE 1;

FIG. 8 is an illustration showing the result of an EBSD analysis performed on a polycrystalline film formed in EXAMPLE 1;

FIG. 9A and FIG. 9B illustrate an example of a TFT manufacturing process according to EXAMPLE 1, and the process is executed in order of FIG. 9A-FIG. 9B;

FIG. 10A and FIG. 10B illustrate another example of the TFT manufacturing process according to EXAMPLE 1, and the process is executed in order of FIG. 10A-FIG. 10B;

FIG. 11 is a conceptual diagram showing a semiconductor thin film manufacturing method according to EXAMPLE 2;

FIG. 12A is a schematic diagram of a polycrystalline film formed according to EXAMPLE 3, and FIG. 12B is a schematic diagram of a polycrystalline film formed according to EXAMPLE 4;

FIG. 13A-FIG. 13C illustrate sectional views showing a TFT manufacturing process, and the process is executed in order of FIG. 13A-FIG. 13C;

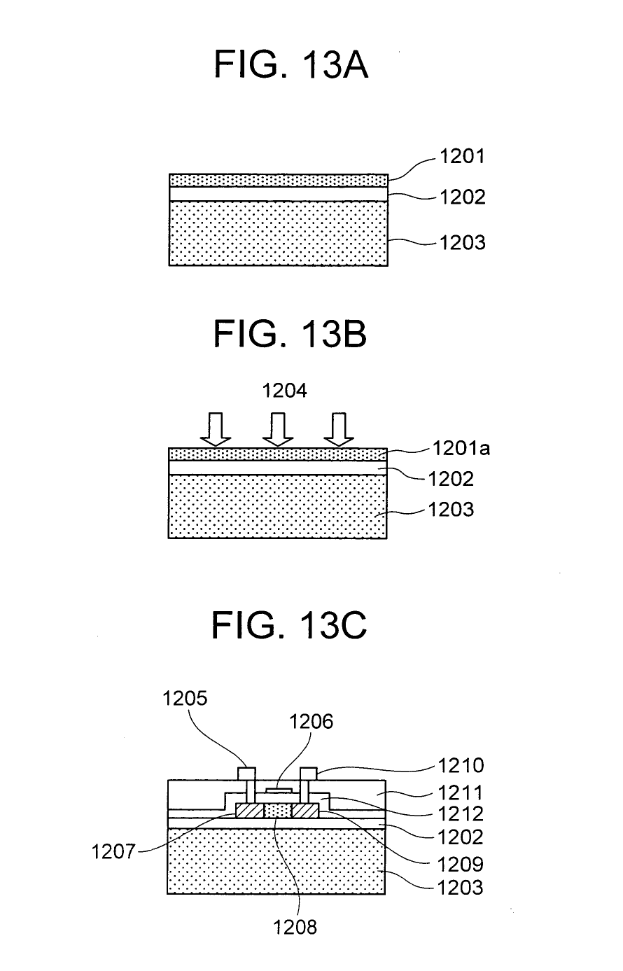

FIG. 14A-FIG. 14E illustrate plan views showing a laser annealing process according to a first related art, and the process is executed in order of FIG. 14A-FIG. 14E; and

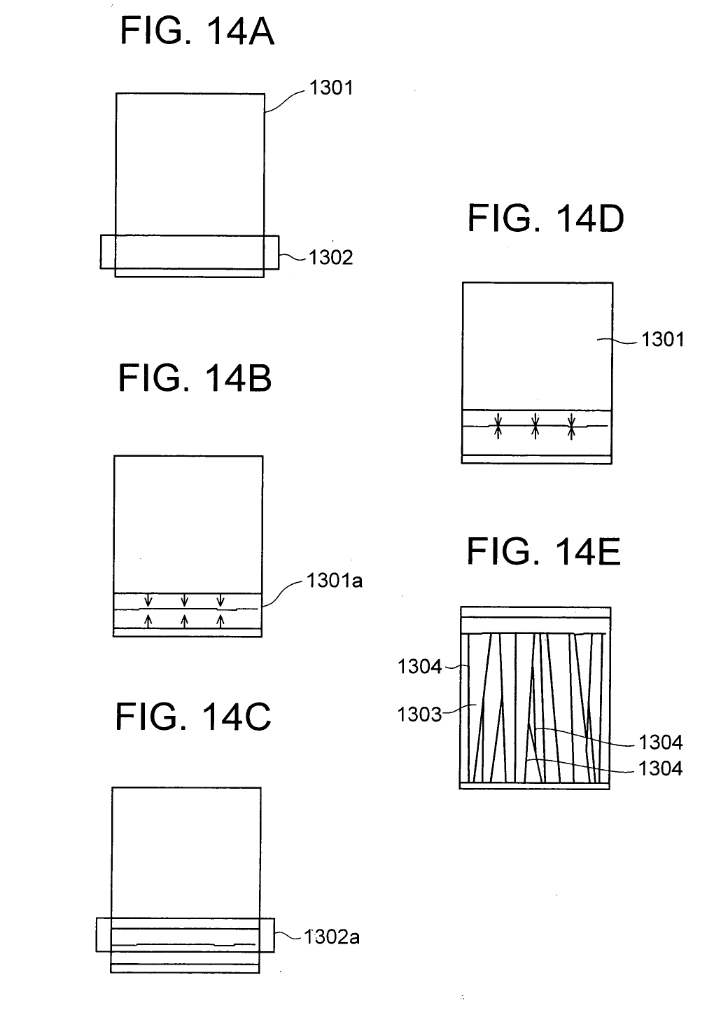

FIG. 15A is a plan view showing a mask according to a second related art, and FIG. 15B is a schematic diagram of a polycrystalline film surface according to the second related art.

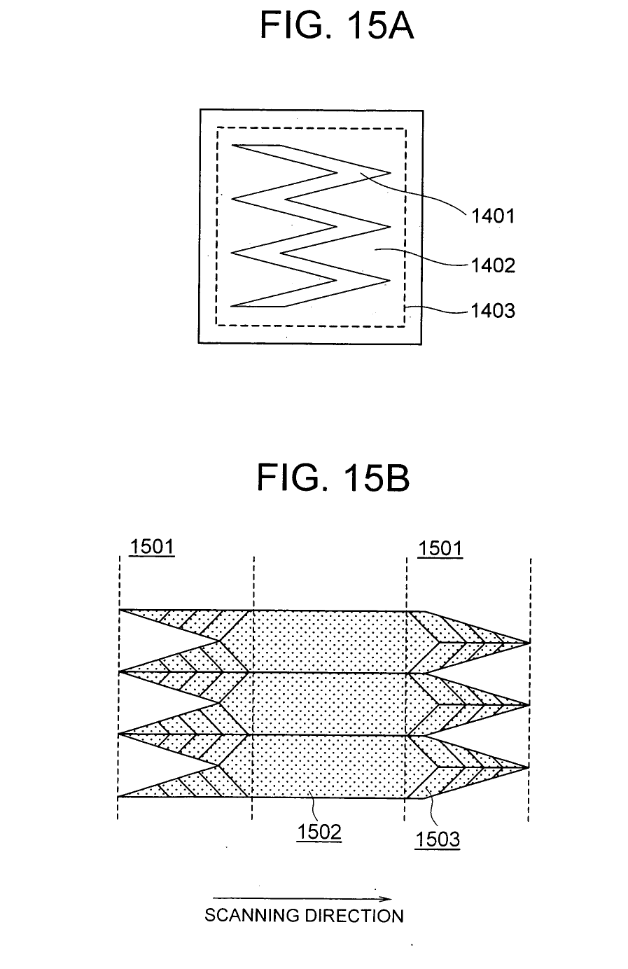

### DETAILED DESCRIPTION OF THE EXEMPLARY EMBODIMENTS

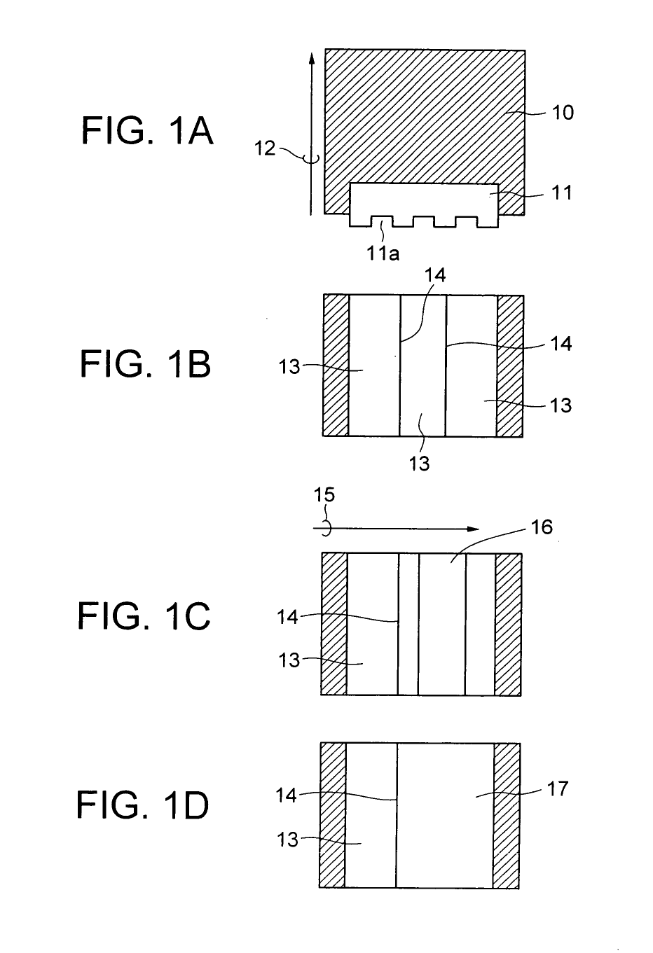

Hereinafter, exemplary embodiments of the invention will be described by referring to the accompanying drawings. FIG. 1 shows conceptual diagrams of an exemplary embodiment. As partly shown in FIG. 1A, a beam pattern 11 including a plurality of recessed patterns 11a is scanned in a first scanning direction 12 on an amorphous silicon 10 that is formed on a glass substrate so as to irradiate the beam in the shape of the beam pattern 11 onto the amorphous silicon 10 (first crystallization step). In this case, the size of the beam pattern 11 in a long-side direction (a second scanning direction) is set in accordance with the width of the silicon 10. Further, the above-described silicon 10 may not have to be an amorphous type but may be already-crystallized silicon or other semiconductor films. By the first crystallization step, a plurality of band-shape crystal grains 13 can be formed side by side as shown in FIG. 1B. The boundaries between the band-shape crystal grains 13 are crystal grain boundaries 14. The number of the recessed pattern 11a included in the beam pattern 11 is not specifically an issue here, as long as the band-shape crystal grains 13 can be formed arranged side by side. Next, as shown in FIG. 1C, a beam pattern 16 is scanned in a second scanning direction 15 that is different from the first scanning direction 12 by 90 degrees so as to irradiate the beam on the amorphous silicon 10 through the beam pattern 16 (second crystallization step). As shown in FIG. 1D, the crystal grain diameter is expanded in the second scanning direction 15 by having the band-shape crystal grains 13 formed by the first crystallization step as seeds. That is, new band-shape crystal grains 17 having the expanded grain diameter can be obtained. This exemplary embodiment will be described hereinafter in a more specific way.

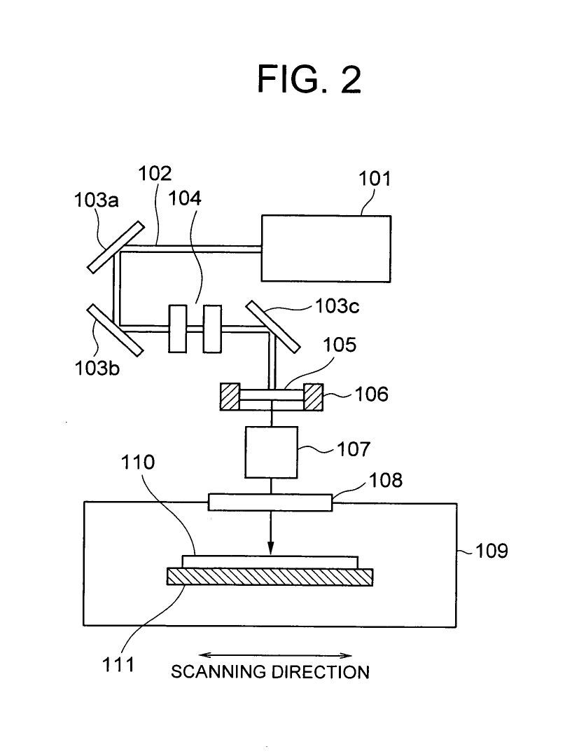

Laser annealing is performed by using a laser annealing device shown in FIG. 2. In FIG. 2, a precursor to be described later is formed on a substrate 110, and the substrate 110 is loaded on a substrate stage 111 within a chamber 109. A laser oscillator 101 is placed on the outer side of the chamber 109, and the laser oscillator 101 outputs XeCl excimer beam (beam 102) with a wavelength of 308 nm by oscillating it in a pulse form. The laser beam (beam 102) is guided to a homogenizer 104 by mirrors 103a, 103b, and it is shaped into a rectangular beam profile by the homogenizer 104. The optical path of the shaped beam 102 is bent towards the lower side by a mirror 103c to be in a beam pattern that is irradiated to the precursor on the substrate 110 through a mask 105 on a mask stage 106. Further, the beam (laser beam) 102 is reduced as necessary by a reducing lens 107, and irradiated to the surface of the precursor on the substrate 110 via a window 108 provided to the chamber 109. The substrate 110 along with the substrate stage 111 can be moved in directions of arrows in FIG. 2, i.e. in directions crossing with the scanning direction. When the beam 102 and the substrate 110 make relative movements, the beam 102 is scanned on the surface of the substrate 110 in the moving direction of the substrate 110. In this device, the beam 102 and the substrate 110 are relatively moved by the substrate stage 111 to scan the beam 102 on the surface of the substrate 110. However, it is not limited to such case. The beam may be scanned on the fixed substrate 110 by moving the mask stage 106 in a horizontal direction.

The mask 105 has a transmitting region made of quartz which transmits a laser beam, and a non-transmitting region formed with chrome on the surface of the quartz for shielding the laser beam. It is also possible to form the non-transmitting region by forming a film with a material that shields laser beam such as aluminum, molybdenum, chrome, tungsten silicide, or a stainless alloy on a material that transmits the laser beam, and then patterning the formed light-shielding member to a necessary shape. Furthermore, a transparent film such as a chromium oxide film as a protection film may be laminated on a light-shielding film on which an aperture for transmitting the laser beam is formed so as to cover the aperture with the transparent film. It is also possible to use a patterned single-layered or multilayered dielectric film as the light-shielding film member. Further, instead of the light-shielding mask, a phase shift mask may be used to shape the beam 102. The above-described mask may be provided at any positions on the optical path of the laser between the laser oscillator 101 and the precursor.

Furthermore, while the above-described exemplary embodiment uses an XeCl excimer laser as the laser oscillator 101, it is not limited only to that. The laser oscillator 101 may be other excimer laser such as a KrF laser. Also, it may be a solid-state laser such as an Nd:YAG laser, Nd:YLF laser, Nd:YVO₄ laser, or a gas laser such as a carbon dioxide gas laser or an argon gas laser.

The substrate 110 is formed by laminating an insulating film and an amorphous silicon film on the glass substrate in order.

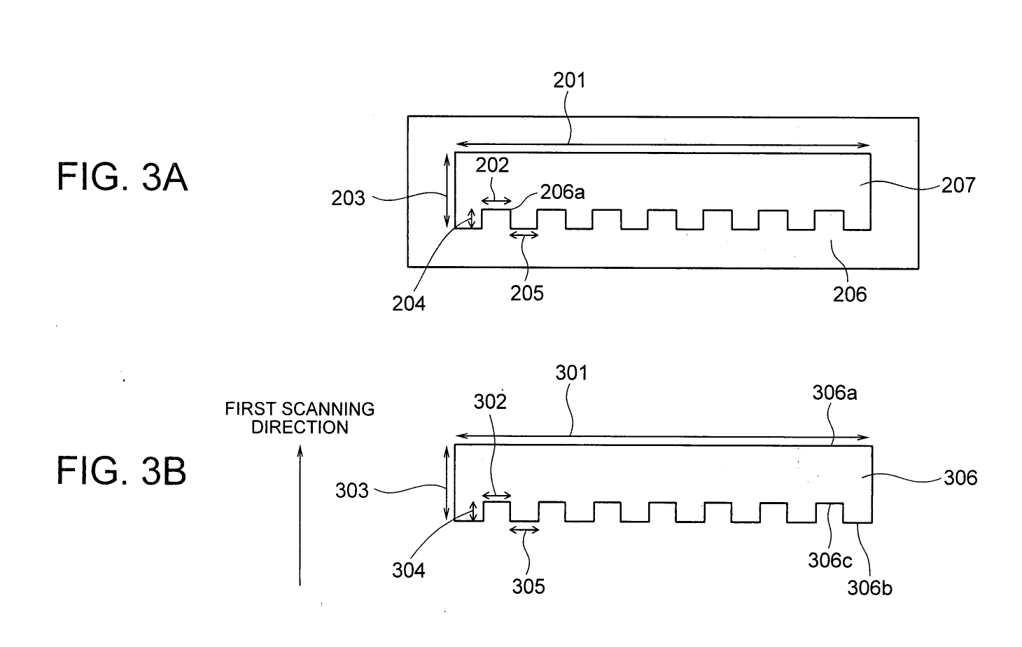

First, the first crystallization step will be described. In this exemplary embodiment, the first crystallization is performed by using a mask as shown in FIG. 3A, which is in a shape where a protruded light-shielding pattern and a recessed pattern are formed periodically, to irradiate a beam through the mask while scanning the mask in the first scanning direction 12. That is, as shown in FIG. 3A, the mask has a light-shielding part 206 for shielding the beam and a transmitting part 207 for transmitting the beam. The external shape of the light-shielding part 206 is formed in a rectangular shape, and the transmitting part 207 is formed within the light-shielding part 206. Provided that the length in the long-side direction is an aperture part length 201 and the length in the short-side direction is an aperture part width 203, the transmitting part 207 is formed in a rectangular shape with a dimensional relation of “the aperture part length 201>the aperture part width 203”. The short-side direction is a direction along the first scanning direction, and the long-side direction is a direction along the second scanning direction.

Further, the light-shielding part 206 has a comb-shaped protruded light-shielding pattern 206a projected inside the transmitting part 207 on one long-side, and the transmitting part 207 has a recessed pattern (corresponds to the recessed pattern 11a of FIG. 1) formed due to the protruded light-shielding pattern 206a of the light-shielding part 206 on one long-side. The comb-shaped protruded light-shielding pattern 206a is obtained by arranging individual protruded parts projected inside the transmitting part 207 with an interval of a protruded part length 205 provided therebetween. The recessed pattern (11a of FIG. 1) is formed by the individual protruded parts of the comb-shaped protruded light-shielding pattern 206a formed on one of the long sides of the transmitting part 207, and each recessed part is formed as a rectangular shape that has the length in the long-side direction as a recessed part length 202 and the length in the short-side direction as a recessed part length 204 by corresponding to the size of each protruded part of the protruded light-shielding pattern 206a. Further, the interval in the recessed pattern (11a of FIG. 1) of the transmitting part 207 of the neighboring transmitting part 207 is set as equal to the protruded part length 205 that is the interval between the individual protruded parts of the protruded light-shielding pattern 206a.

When the beam is shaped by being transmitted through the mask shown in FIG. 3A, it is shaped into a form of a beam pattern 306 shown in FIG. 3B. When the beam is transmitted through the mask shown in FIG. 3A, the beam is shielded by the light-shielding part 206 and let through the transmitting part 207, and it is shaped into the beam pattern 306 shown in FIG. 3B. Provided that the length of a long side 306a (306b) is a beam length 301 and the length in a short-side direction is a beam width 303, the beam pattern 306 is shaped into a rectangular shape with a dimensional relation of “the beam length 301>the beam width 303”. The beam length 301 of the beam pattern 306 is a size that corresponds to the aperture part length 201 of the transmitting part 207 of the mask, and the beam width 303 of the beam pattern 306 is a size that corresponds to the aperture width 203 of the transmitting part 207 of the mask.

Further, when the beam transmits through the mask shown in FIG. 3A, a part of the beam is shielded by the protruded light-shielding pattern 206a and it transmits through the recessed pattern of the transmitting part 207 when transmitting through the long-side of the mask, since the transmitting part 207 of the mask shown in FIG. 3A has the recessed pattern (11a of FIG. 1) on the long side formed due to the protruded light-shielding pattern 206a. Thereby, a recessed pattern 306c comes to be shaped on the long side 306b of the beam pattern 306. Therefore, as shown in FIG. 3B, the beam pattern 306 of the beam that is shaped by transmitting through the mask has, on the long side 306b, the recessed part 306c that is shaped by transmitting through the recessed pattern (11a of FIG. 1) of the transmitting part 207. The recessed pattern 306c of the beam pattern 306 is a pattern where the recessed parts, each having the length in the long-side direction as a beam recessed part length 302 and the length in the short-side direction as a beam recessed part width 304, are lined along the long-side direction at an interval of the beam protruded part length 302.

The beam recessed part width 304 of each recessed part that configures the recessed pattern 306c of the beam pattern 306 is a size that corresponds to the recessed part length 204 of the recessed pattern of the transmitting part 207. The beam recessed part length 302 of each recessed part that configures the recessed pattern 306c is a size that corresponds to the recessed part length 202 of the recessed pattern of the transmitting part 207. The beam protruded part length 305 that is the length of the interval between each of the recessed parts of the recessed pattern 306c is a size that corresponds to the protruded part length 205 of the recessed pattern of the transmitting part 207.

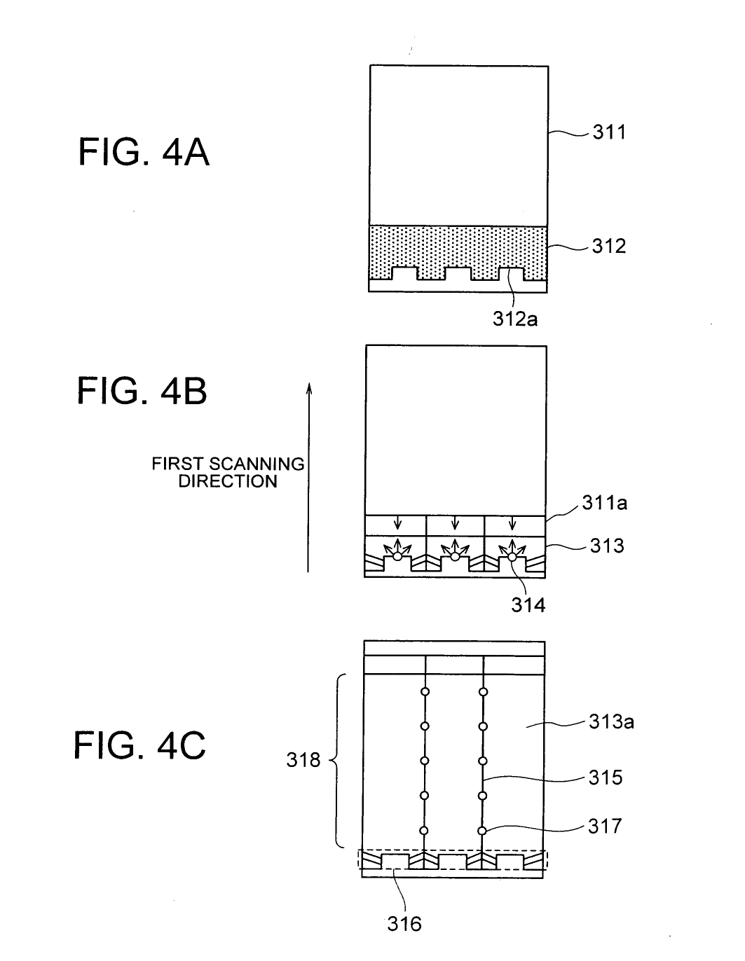

In FIG. 4A, amorphous silicon is used as a precursor that is made of a semiconductor film to be formed on an insulating substrate. As shown in FIG. 4A, a beam is irradiated to the mask of FIG. 3A to shape it into the beam pattern 306 of FIG. 3B, and the beam pattern 306 is irradiated to the amorphous silicon 311 as a first beam pattern 312. Through irradiating the beam pattern 312, temperature gradient is formed radially from the tips of a recessed pattern 312a (corresponds to the recessed pattern 306c of FIG. 3B) of the beam pattern 312 in a region of the amorphous silicon 311 to which the beam pattern 312 is irradiated.

Therefore, as shown in FIG. 4B, by having crystalline germs 314 as the seeds, crystal grains 313 are grown and formed in the region of the amorphous silicon 311, which corresponds to the tips of the recessed pattern 312a not only in the beam width direction (the direction of the beam width 303 in FIG. 3B) but also in the beam length direction (the direction of the beam length 301 in FIG. 3B). Further, polycrystalline silicon 311a is grown in the first scanning direction. Through performing irradiation of the beam pattern 312 for the second time and thereafter, the crystal grains 313 are repeatedly grown by having the crystalline germs 314 that are formed on the amorphous silicon 311 by corresponding to the tips of the recessed pattern 312a as the seeds. As a result, as shown in FIG. 4C, the band-shape crystal grains 313a with a wider width than the case of irradiating a widely-used thin-linear beam are formed on the amorphous silicon 311 by having the tips of the recessed pattern 312a as the starting points. In FIG. 4B, the first scanning direction of the beam pattern 312 is illustrated with an arrow.

Further, the sizes of the beam recessed part width 304 and the beam recessed part length 302 of the recessed pattern 306c of FIG. 3B that corresponds to the recessed pattern 312a are set to be equal to or smaller than the crystal grain diameter in the scanning direction of the beam pattern 312 and in the direction crossing with the scanning direction (perpendicular direction) so as to sequentially form the band-shape crystal grains 313 side by side in the direction crossing with the scanning direction. At this time, it is not necessary for all of a plurality of beam recessed part lengths 305 as the intervals between the neighboring recessed patterns 312a (FIG. 3B) to be set equal. The recessed patterns 312a (recessed patterns 306c of FIG. 3B) may be arranged as appropriate so as to form the band-shape crystal grains 313 at prescribed positions. As described, it is possible with the exemplary embodiment to reduce the number of crystal grain boundaries 315 in the semiconductor thin film as shown in FIG. 4C, and to manufacture the semiconductor thin film in which the forming directions of the crystal grains 315 are controlled to be in a parallel positional relation. With this, the issues raised by irradiating the widely-used thin-linear beam can be solved.

Further, as shown in FIG. 4C, dot-shape protrusions 317 are formed along the crystal grain boundaries 315 at a scanning step interval of the beam pattern 312. Thus, it is possible with the exemplary embodiment to obtain a semiconductor thin film on which the protrusions 317 are formed in a grid form. When manufacturing TFTs on such semiconductor thin film, the layout and the number of the protrusions 317 within the channel can be controlled. Thus, variations in the threshold voltage can be made smaller compared to a case of TFTs fabricated by the thin-linear beam, in which the layout and the number of protrusions within the channel become random. Furthermore, the variations in the threshold voltage can be suppressed more through forming the channel by avoiding the protrusions 317. In FIG. 4C, three band-shape crystal regions 318 divided by the crystal grain boundaries 315 are formed along the length direction of the parallel crystal grain boundaries 315. The number of the band-shape crystal regions 318 is not limited to three. Each of the band-shape crystal regions 318 is formed by a single crystal.

Further, since the transmittance of the laser beam of this case is larger than that of the zigzag pattern, the beam length can be made longer. Thus, the laser annealing processing time per substrate can be shortened by expanding the area of one-time scan-irradiation. Furthermore, by shortening the beam recessed part width (the beam recessed part width 304 of FIG. 3) of the recessed pattern 312a, it is possible to narrow highly-dense grain boundary regions 316 that are generated on the amorphous silicon 311 by corresponding to the beam irradiation start positions, compared to the case of the zigzag pattern. Further, as shown in FIG. 3B, the side 306a that is the front side of the beam pattern 306 is a straight line extending in a direction perpendicular to the scanning direction. Thus, the highly-dense grain boundary regions 316 generated at the beam irradiation end positions on the amorphous silicon 311 are about the size of the crystal growth distance obtained by one-time irradiation. The highly-dense grain boundary regions generated at the beam irradiation end positions in the case of the zigzag pattern become wider since the regions are about the size of the sum of the scanning direction of the zigzag pattern and the crystal growth distance obtained by one-time irradiation. Further, the mask manufacturing process for the recessed pattern 306c is simpler compared to that of the zigzag pattern, so that the manufacturing cost can be reduced. Furthermore, unlike the case of forming the zigzag pattern, it is unnecessary for the optical system for laser annealing to have high resolution in the case of forming the recessed pattern 306c of the beam pattern 306. Because of the reasons described above, the issues of the case of using the zigzag pattern beam can be solved.

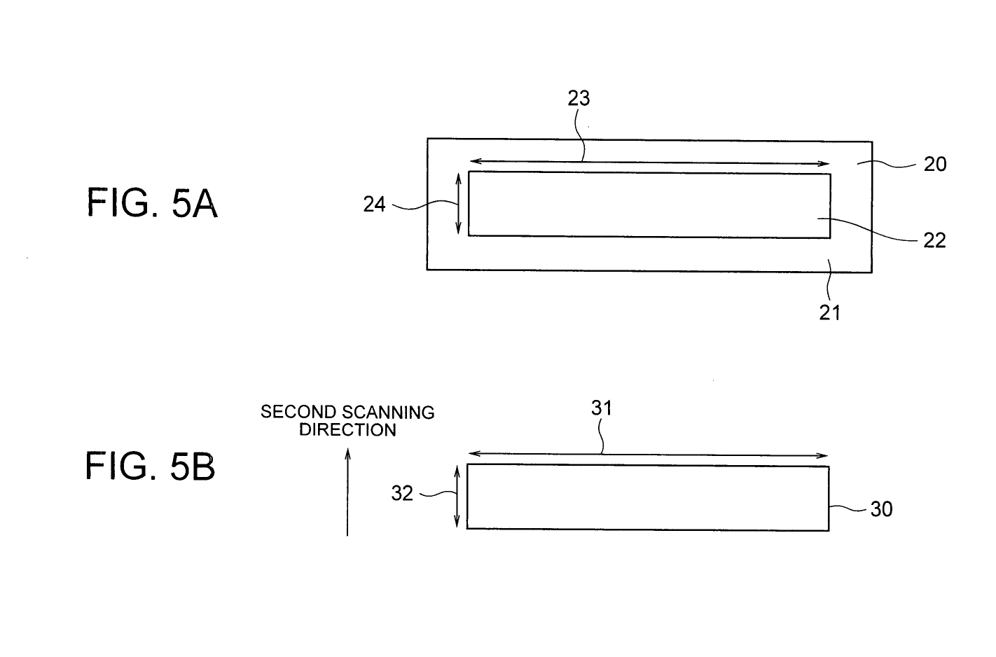

Next, the second crystallization step will be described by referring to FIG. 2 and FIG. 5. Following the first crystallization step, the substrate 110 on which the band-shape crystal grains are formed is loaded on the substrate stage 111 by rotated it by 90 degrees in the horizontal direction, and a beam pattern 30 is scan-irradiated in a direction (second scanning direction) perpendicular to the scanning direction (first scanning direction) of the first crystallization to perform the second crystallization. At this time, the substrate stage 111 may be rotated by 90 degrees in the horizontal direction while having the substrate 110 loaded thereon. Further, in a case where scan-irradiation is performed by moving the mask stage 106, the moving direction of the mask stage 106 may be rotated by 90 degrees in the horizontal direction without moving the substrate 110 and the substrate stage 111.

The beam pattern 30 of the second crystallization is shaped as in FIG. 5B by using a rectangular mask 20 as shown in FIG. 5A. As shown in FIG. 5A, the mask pattern 20 is configured with a light-shielding part 21 that shields the light and a transmitting part 22 that transmits the light. The light-shielding part 21 is a rectangular frame shape, and the transmitting part 22 is formed in a rectangular shape within the light-shielding part 21. Provided that the length in the long-side direction is an aperture part length 23 and the length in the short-side direction is an aperture part width 24, the transmitting part 22 is formed in a rectangular shape with a dimensional relation of “the aperture part length 23>the aperture part width 24”. The short-side direction is the second scanning direction.

As shown in FIG. 5B, provided that the length in the long-side direction is a beam length 31 and the length in the short-side direction is a beam width 32, the beam pattern 30 that is being shaped by irradiating the beam to the mask 20 shown in FIG. 5A is shaped into a rectangular shape with a dimensional relation of “the beam length 31>the beam width 32”. The beam length 31 of the beam pattern 30 shown in FIG. 5B corresponds to the aperture part length 23 of the transmitting part 22 of the mask 20 shown in FIG. 5A, and the beam width 32 of the beam pattern 30 corresponds to the aperture width 24 of the transmitting part 22. As shown in the drawing, the beam length 31 and the beam width 32 of the beam pattern 30 are determined with respect to the second scanning direction.

The band-shape crystal grains obtained by the first crystallization can be extended in the second scanning direction by performing the second crystallization. Further, the main plane azimuth of the obtained semiconductor thin film is (100), the main azimuth of the first scanning direction is <110>, and the main azimuth of the second scanning direction is <110>. The beam pattern is not necessarily in a rectangular shape. For example, the mask used in the first crystallization may be used as it is.

In the TFT fabricated by using the obtained semiconductor thin film, the carrier mobility can be improved and the variations in the mobility and threshold voltage can be suppressed. While the exemplary embodiment has been described by referring to the case where the recessed pattern 306c is in a rectangular shape, it is not limited only to that. The recessed pattern 306c may be in a polygonal shape such as a triangle, or may be in a semicircular shape, a semi-elliptic shape, or the like.

In summary, the exemplary embodiment of the invention is directed to a semiconductor thin film manufacturing method which irradiates a laser beam to a semiconductor thin film formed on an insulating substrate so as to grow a crystal film on the semiconductor thin film. In this method, after performing the first crystallization through scan-irradiating a laser beam having a part of irradiation pattern thereof irradiated on the semiconductor thin film is shaped into a controlled pattern (recessed pattern) that is used for controlling the positions of the crystal grain boundaries that are formed on the semiconductor thin film, the second crystallization is performed by executing scan-irradiation in a direction that is different from the scanning direction of the first crystallization.

### EXAMPLE 1

EXAMPLE 1 will be described by referring to FIG. 1. As shown in FIG. 1A, a beam pattern 11 including a plurality of recessed patterns 11a is scan-irradiated to an amorphous silicon 10 formed on a glass substrate in a first scanning direction 12 (first crystallization step). At this time, the above-mentioned silicon may not necessarily be an amorphous type but may be already-crystallized silicon or other semiconductor thin films. Further, it is not necessary to include a plurality of recessed patterns 11a. As shown in FIG. 1B, a plurality of band-shape crystal grains 13 can be formed side by side by the first crystallization. Then, as shown in FIG. 1C, a beam pattern 16 is scanned in a second scanning direction 15 that is different from the first scanning direction 12 by 90 degrees (second crystallization). As shown in FIG. 1D, by having the band-shape crystal grains 13 formed in the first crystallization step as the seeds, new band-shape crystal grains 17 having the expanded grain diameter in the second scanning direction 15 can be obtained.

A concrete example thereof will be described hereinafter. Laser annealing was performed by using the laser annealing device shown in FIG. 2. The method, the mask, and the laser used therein were those described in the exemplary embodiment. Further, for the aperture part and the transmitting part, a large number of slits with extremely narrow width may be lined to be the aperture part and the like or a large number of holes may be opened closely to be the aperture part and the like. In theses cases, the energy of the laser beam can be adjusted by changing the number of slits or the number and the density of the holes. Now, the substrate will be described. An alkali-free glass was used as a glass substrate. An insulating film was formed on the glass substrate for preventing diffusion of impurities from the glass. An amorphous silicon film of 60 nm was formed as a precursor on the insulating film by using low pressure chemical vapor deposition (LP-CVD).

In EXAMPLE 1, a beam pattern shaped by using a mask in which the recessed pattern was formed periodically as in FIG. 3 was scan-irradiated to perform the first crystallization. The irradiation condition of the first crystallization is shown in Table 1. The irradiation intensity is a value on the substrate. The step width of the laser beam scanning is a distance on the substrate that is scanned by the laser beam during irradiation of each rectangular beam pattern. The aperture part width, the recessed part length, the recessed part width, and the protruded part length in Table 1 are the values on the mask. The beam pattern passed through the mask comes to be in the shape as shown in FIG. 3B on the substrate. The beam size on the substrate becomes one third of the beam size on the mask. That is, the beam width is 6 μm, the beam recessed part length is 1 μm, the beam recessed part width is 3 μm, and the beam protruded part length is 1 μm.

After the first crystallization, the substrate was rotated by 90 degrees and loaded again on the substrate stage. After adjusting the position of the stage in such a manner that the irradiation start position come on the band-shape crystal grain, a beam pattern shaped by using a rectangular mask as shown in FIG. 5A was scan-irradiated in a direction (second scanning direction) perpendicular to the scanning direction (first scanning direction) of the first crystallization so as to perform the second crystallization. At this time, even though there was an angle difference of 90 degrees between the first scanning direction and the second scanning direction on the substrate, those were the same direction on the substrate stage.

The irradiation condition of the second crystallization is shown in Table 2. The step width of the laser beam scanning is a distance on the substrate that is scanned by the laser beam during irradiation of each rectangular beam pattern. The aperture part width in Table 2 is the value on the mask. The beam size on the substrate becomes one third of the beam size on the mask. That is, the beam width is 3.3 μm.

TABLE 1
EXAMPLE 1 (First Crystallization Step)

| | |
|---|---|
| Irradiation intensity (mJ/cm²) | 600 |
| Step width (μm) | 0.2 |
| Aperture part width (μm) | 18 |
| Recessed part length (μm) | 3 |
| Recessed part width (μm) | 9 |
| Protruded part length (μm) | 3 |

TABLE 2
EXAMPLE 1 (Second Crystallization Step)

| | |
|---|---|
| Irradiation intensity (mJ/cm²) | 600 |
| Step width (μm) | 0.2 |
| Aperture part width (μm) | 9.9 |

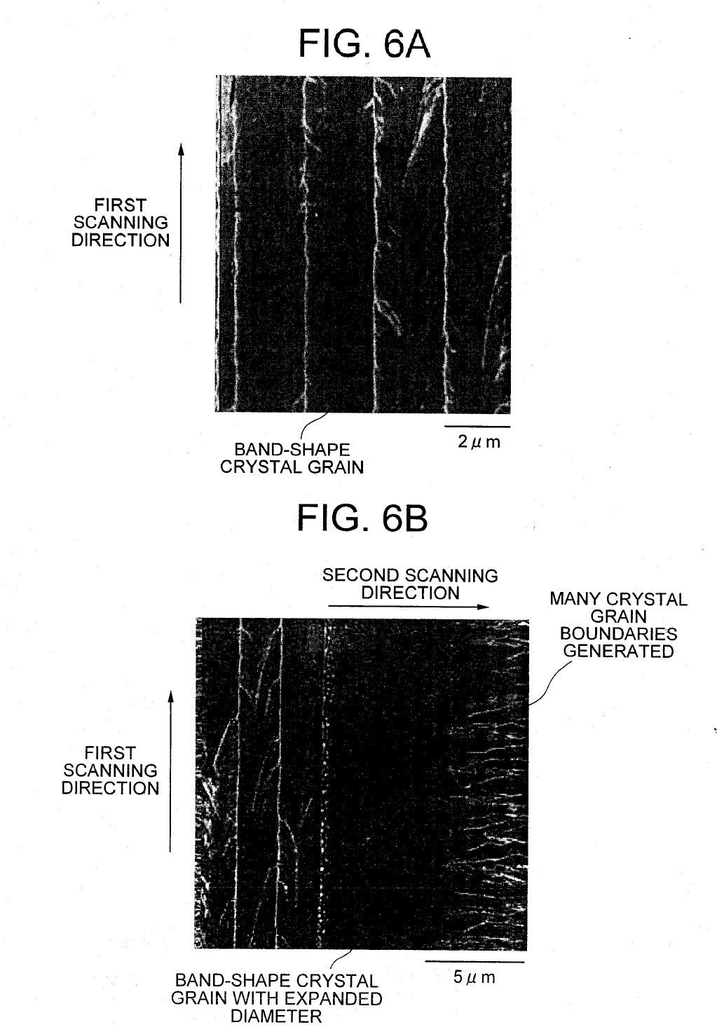

FIG. 6A shows the result of SEM observation performed on the crystallized film to which Secco-etching processing was applied after the first crystallization. Band-shape crystal regions with the crystal growth width of 2 μm were formed by being lined in parallel in the scanning direction from the tips of each recessed pattern. In EXAMPLE 1, the case of using a periodic pattern in which each recessed pattern is arranged periodically was described. However, it is not necessary to form all the recessed patterns at equal intervals. It can be designed as appropriate so as to form the band-shape crystal regions in desired positions. Further, the preferable beam recessed part length varies depending on the film thickness or the film forming method of the precursor film, the beam irradiation intensity, or the resolution of the optical system. Therefore, the beam recessed part length may be designed as appropriate in accordance with the conditions.

From FIG. 6A, it can be seen that the crystal grain boundaries of the band-shape crystal grains are generated in parallel to the first scanning direction. Therefore, by arranging the side of the beam pattern on the opposite side of the scanning direction to become in parallel to the first scanning direction at the time of starting the irradiation for the second crystallization, it becomes possible to start the scan-irradiation without having that side crossing with the crystal grain boundaries of the band-shape crystal grains formed by the first crystallization. This makes it possible to fabricate crystal grains that are wider than the related cases when promoting the crystal growth in the second scanning direction. At the same time, it is possible to suppress generation of random crystal grain boundaries.

More specifically, by providing a difference of about 90 degrees, for example, between the first scanning direction and the second scanning direction, it becomes possible to fabricate crystal grains that are wider than the related cases when promoting the crystal growth in the second scanning direction, and to suppress generation of random crystal grain boundaries. Further, by having the side of the beam pattern that is opposite from the scanning direction to be in a linear form in the second crystallization, it becomes possible to fabricate crystal grains that are wider than the related cases when promoting the crystal growth in the second scanning direction, and to suppress generation of random crystal grain boundaries.

FIG. 6A shows the result of SEM observation performed on the crystallized film to which Secco-etching processing was applied after the second crystallization. The angle difference between the first scanning direction and the second scanning direction was 90 degrees. The crystals were grown in the second scanning direction by using the band-shape crystal grains formed by the first crystallization as the seeds. The grain diameters of the obtained crystal grains (the band-shape crystal grains whose grain diameters were expanded) in the second scanning direction were expanded in an average of 7 μm. In the method for expanding the diameters of the crystal grains formed by the first crystallization through performing the second crystallization by using the crystal grains formed by the first crystallization as the seeds, abeam pattern including at least one or more recessed patterns on the side that was opposite from the scanning direction of the beam of the first crystallization was used to achieve control of the crystal grain positions. Through performing the second crystallization by using the position-controlled band-shape crystal grains as the seed crystals, single-crystal grains were formed over the width of more than the vertical direction of the photograph as in FIG. 6B. That is, it was able to form the crystal grains wider than the related cases, and to suppress generation of random crystal grain boundaries.

Further, since the transmittance of the laser beam was larger than that of the zigzag pattern, it was possible to make the beam length longer. Thus, the laser annealing processing time per substrate could be shortened by expanding the area of one-time scan-irradiation. Furthermore, a plurality of the band-shape crystal grains to be the seed crystals were formed side by side in the first crystallization, so that the margins of the scan-irradiation start positions were expanded in the second crystallization. This provides such an effect that it is unnecessary for the laser annealing device to have a sophisticated alignment performance. Moreover, since the recessed pattern has no acute angle, so that the manufacturing cost can be reduced and it is unnecessary for the optical system used for laser annealing to have high resolution. By using the band-shape crystal grains with the expanded grain diameters for the active layer, it is expected to achieve fabrication of TFT that exhibits high mobility and small variations in the performance. Further, expansion of the crystal grain diameter provides such effects that restriction in the channel size of the TFT can be modified and that it is unnecessary to have a high-resolution and sophisticated alignment mechanism for fabricating the TFT.

From FIG. 6B, it can be seen that a large number of crystal grain boundaries were generated as the scan-irradiation was advanced to some extent in the second crystallization. The crystal grain diameter in the second scanning direction in EXAMPLE 1 was about 20 μm at the most. Because of the above, in order to form the crystal grains with the large grain diameters with high efficiency, it is desirable to suppress the scanning distance to be about 20 μm or less and to form one or more irradiation areas. It is known that the maximum value of the crystal grain boundaries in the second scanning direction varies depending on the type of the laser, the irradiation intensity, the step width, the film thickness of the silicon film, the film structure of the undercoating of the silicon film, the forming method of the amorphous silicon, the washing condition of the substrate performed right before the laser annealing, etc. Thus, the scanning distance may be designed as appropriate in accordance with those conditions.

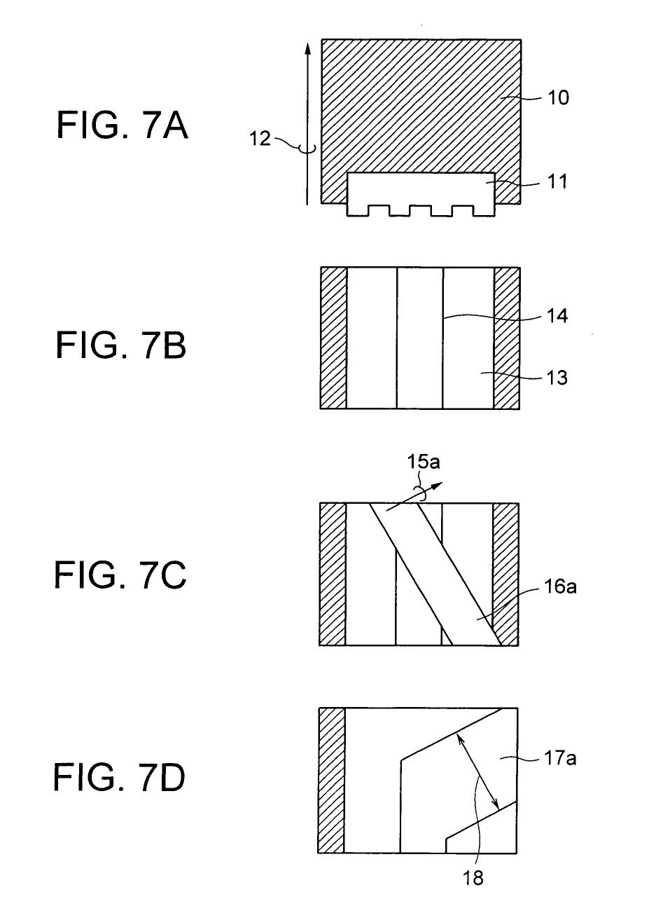

While the angle difference between the first scanning direction and the second scanning direction was set as 90 degrees in EXAMPLE 1, it is not limited only to that. It is possible to expand the width of the band-shape crystal grains as long as the angle of the first scanning direction and that of the second scanning direction were different. Thus, the angle therebetween may be designed as appropriate in accordance with a desired crystal grain diameter, TFT layout, and the like. For example, as shown in FIG. 7, when the angle difference between the first scanning direction 12 and the second scanning direction 15a is set as 60 degrees, band-shape crystal grains 17a with a width of almost twice the width of the band-shape crystal grains 13 that are formed in the first crystallization can be formed side by side in a direction that is perpendicular to the second scanning direction 15a.

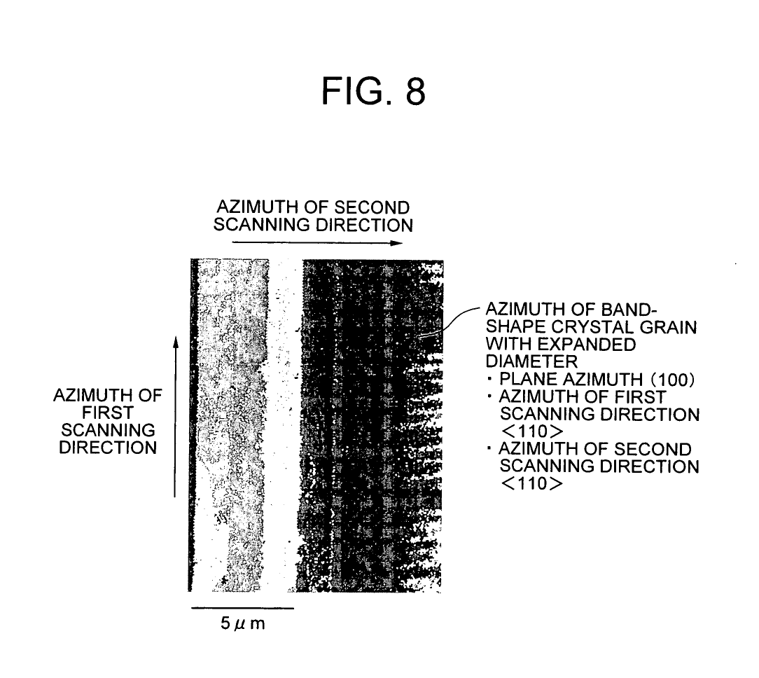

The azimuth distribution of the crystallized film after performing the second crystallization was analyzed by EBSD (Electron Backscatter Diffraction) method. FIG. 8 shows the result. A range within a margin of 5 degrees in the azimuth angle from the neighboring measuring points is considered as the same direction, and the same azimuth is expressed with a same luminosity. The main plain azimuth of the band-shape crystal grains with the enlarged grain diameters was (100), and the azimuth inside the crystal grain was distributed within a range that was different by 15 degrees with respect to (100). Further, the main azimuth of the first scanning direction was <110>, and the azimuth inside the crystal grain was distributed within a range that was different by 15 degrees with respect to <110>. Furthermore, the main azimuth of the second scanning direction was <110>, and the azimuth inside the crystal grain was distributed within a range that was different by 15 degrees with respect to <110>. Even though FIG. 8 shows a black-and-white image, it is actually a color image and each color shows an azimuth angle difference with respect to (100). It can be seen from those colors that the azimuth inside the crystal grain is distributed within a range that is different by 15 degrees with respect to (100), etc., as described above.

The use of the crystallization method of EXAMPLE 1 made it possible to grow the band-shape crystal grains with the main plane azimuth (100) obtained by the first crystallization step, while keeping the main azimuth of the second scanning direction as <110> in the second crystallization step. Further, in the first crystallization step, it was able to achieve growth of the band-shape crystal grains while controlling the azimuth of the second scanning direction to have the azimuth angle difference with respect to (100) to be 15 degrees or less. Furthermore, in the second crystallization step, it was able to achieve growth of the band-shape crystal grains while controlling the plane azimuth angle difference with respect to <110> to be 15 degrees or less. Because of these, the crystal grains with more stable azimuth can be formed than the case of using the related method. Thus, it is expected to suppress variations in the TFT characteristic within the substrate plane.

The use of the crystallization method of EXAMPLE 1 made it possible to control the main azimuth of the first scanning direction for the obtained semiconductor thin film to be <110> preferentially. Further, it was able to control the main azimuth of the second scanning direction for the band-shape crystal grains with the expanded grain diameters to be <110> preferentially. Furthermore, it was able to control the main plane azimuth of the band-shape crystal grains with the expanded grain diameter to be (100). Because of these, the crystal grains with more stable azimuth can be formed than the case of using the related method. Thus, it is expected to suppress variations in the TFT characteristic within the substrate plane.

The use of the crystallization method of EXAMPLE 1 made it possible to control the azimuth of the first scanning direction for the obtained semiconductor thin film to have the azimuth angle difference of 15 degrees or less with respect to <110>. Further, it was able to control the azimuth of the second scanning direction for the band-shape crystal grains with the expanded grain diameter to have the azimuth angle difference of 15 degrees or less with respect to <110>. Furthermore, it was able to control the plane azimuth of the band-shape crystal grains with the expanded grain diameters to have the azimuth angle difference of 15 degrees or less with respect to (100). Because of these, the crystal grains with more stable azimuth can be formed than the case of using the related method. Thus, it is expected to suppress variations in the TFT characteristic within the substrate plane.

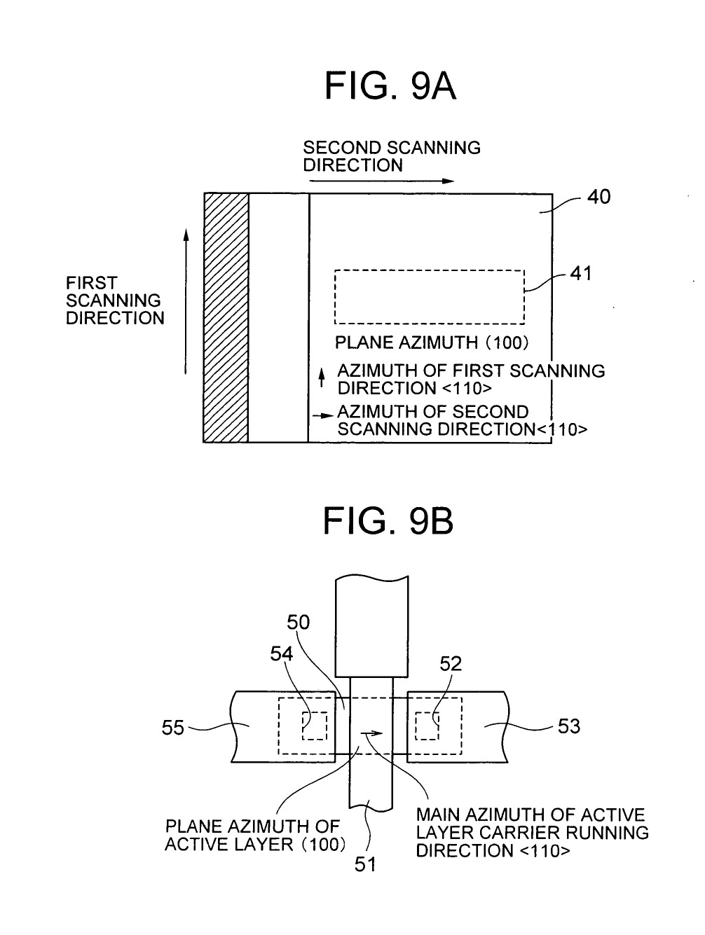

Then, as shown in FIG. 9A, an island area 41 was formed in the obtained crystal film, i.e. in a band-type crystal grain 40 with the expanded grain diameter. This island area 41 was formed in a rectangular shape having the length of 12 μm in the first scanning direction and the length of 4 μm in the second scanning direction. The carriers within an active layer were to move in the first scanning direction. Therefore, a drain region and a source region were formed in the first scanning direction with the active layer interposed therebetween.

Then, as shown in FIG. 9B, a gate electrode 51 was formed on the active layer 50 via a gate insulating film (not shown), a drain electrode 53 was formed on the drain region (reference numeral is omitted) via a contact 52 and, similarly, a source electrode 55 was formed on the source region (reference numeral is omitted) via a contact 54. The contacts 52 and 54 were formed in the insulating film, not shown. Then, an n-type TFT and a p-type TFT with 4 μm in the channel length as well as in the channel width of the active layer 50a were fabricated in such a manner that the moving direction of the carries became the first scanning direction. At this time, the main plane azimuth of the active layer for the surface of the gate insulating film of the TFT was (100), and the main azimuth of the carrier running direction was <110>. The carrier mobility in the obtained TFT was 620 cm²/Vs for the n-type and 220 cm²/Vs for the p-type. Note here that it is desirable to set the channel width as 10 μm or less and more preferably as 7 μm or less for forming the channel in a single-crystal region. Further, the variation (a) in the threshold voltage for one-hundred pieces of n-type TFT was 0.1 V.

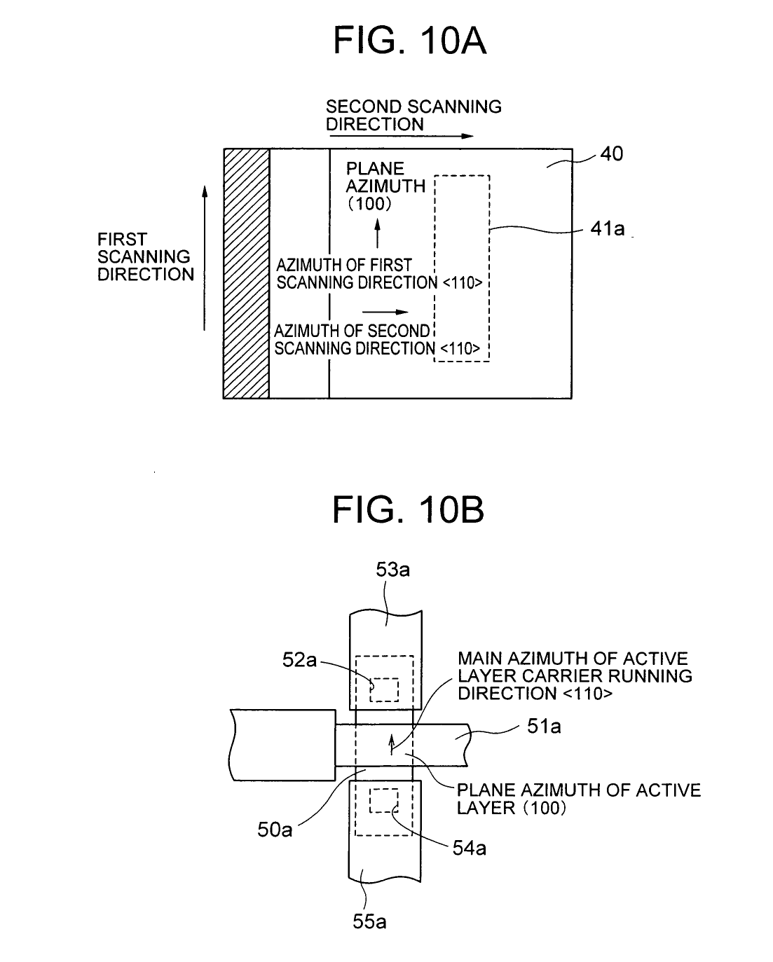

Further, as shown in FIG. 10A, an island area 41a was formed in the obtained crystal film, i.e. in the band-type crystal grain 40 with the expanded grain diameter. A drain region and a source region were formed in the second scanning direction with the active layer interposed therebetween so that the carriers within the active layer were to move in the second scanning direction.

Then, as shown in FIG. 10B, a gate electrode 51a was formed on an active layer 50a via a gate insulating film (not shown), a drain electrode 53a was formed on the drain region (reference numeral is omitted) via a contact 52a and, similarly, a source electrode 55a was formed on the source region (reference numeral is omitted) via a contact 54a. The contacts 52a and 54a were formed in the insulating film, not shown. Then, an n-type TFT and a p-type TFT with 4 μm in the channel length as well as in the channel width of the active layer 50a were fabricated in such a manner that the moving direction of the carries became the second scanning direction. At this time, the main plane azimuth of the active layer for the surface of the gate insulating film of the TFT was (100), and the main azimuth of the carrier running direction was <110>. The carrier mobility in the obtained TFT was 610 cm²/Vs for the n-type and 210 cm²/Vs for the p-type. Note here that it is desirable to set the channel length as 10 μm or less and more preferably as 7 μm or less for forming the channel in a single-crystal region. Further, the variation (σ) in the threshold voltage for one-hundred pieces of n-type TFT was 0.1 V.

For making a comparison, a beam pattern shaped to have the opening part length of 270 μm (90 μm on the substrate) and the opening part width of 9.9 μm (3.3 μm on the substrate) by a thin-linear pattern mask was scan-irradiated over a length of 300 μm by using a same laser annealing device as that of EXAMPLE 1 so as to fabricate a polycrystalline film.

The semiconductor thin film obtained as a comparative example had protrusions formed randomly. The irradiation intensity was 600 mJ/cm² on the substrate, and the step width was 0.2 μm on the substrate. Then, an n-type TFT and a p-type TFT with 4 μm in the channel length as well as in the channel width were fabricated by providing the channel in such a manner that the carries move in parallel with the scanning direction. Since the crystal grain boundary positions were not controlled, there were crystal grain boundaries formed within the channel. The carrier mobility in the obtained TFT was 320 cm²/Vs for the n-type and 120 cm²/Vs for the p-type. Further, the variation (σ) in the threshold voltage for one-hundred pieces of n-type TFT was 0.25 V.

From the comparison of the mobility of the two types of TFTs (EXAMPLE and comparative example), it is obvious that the TFT that satisfies the requirements of the present invention can achieve the higher mobility than that of the related TFT. Therefore, the present invention is capable of achieving fabrication of TFT that exhibits higher performance than that of the related case.

In the band-shape crystal grains with the expanded grain diameters formed by the crystallization method of EXAMPLE 1, the azimuth in the first scanning direction can be controlled as <110> and the azimuth in the second scanning direction can be controlled as <110>. Thus, by designing the carrier moving direction to be in parallel with the first scanning direction or the second scanning direction, it is possible to fabricate the TFT in which the plane azimuth of the active layer and the azimuth of the carrier running direction are controlled as described above. This makes it possible to suppress the variation in the TFT characteristic within the substrate plane compared to the related case.

The use of the band-shape crystal grains with the expanded grain diameters formed by the crystallization method of EXAMPLE 1 as the active layer made it possible to fabricate the TFT in which the angle difference of the plane azimuth of the active layer with respect to (100) was controlled to be 15 degrees or less. Further, the use thereof made it possible to fabricate the TFT in which the angle difference of the azimuth of the carrier running direction with respect to <110> was controlled to be 15 degrees or less. From the results of the above, it is evident that the variation in the TFT characteristic within the substrate plane of such TFT obtained thereby can be suppressed. Therefore, it is clear that the present invention is capable of achieving fabrication of high-performance TFT.

### EXAMPLE 2

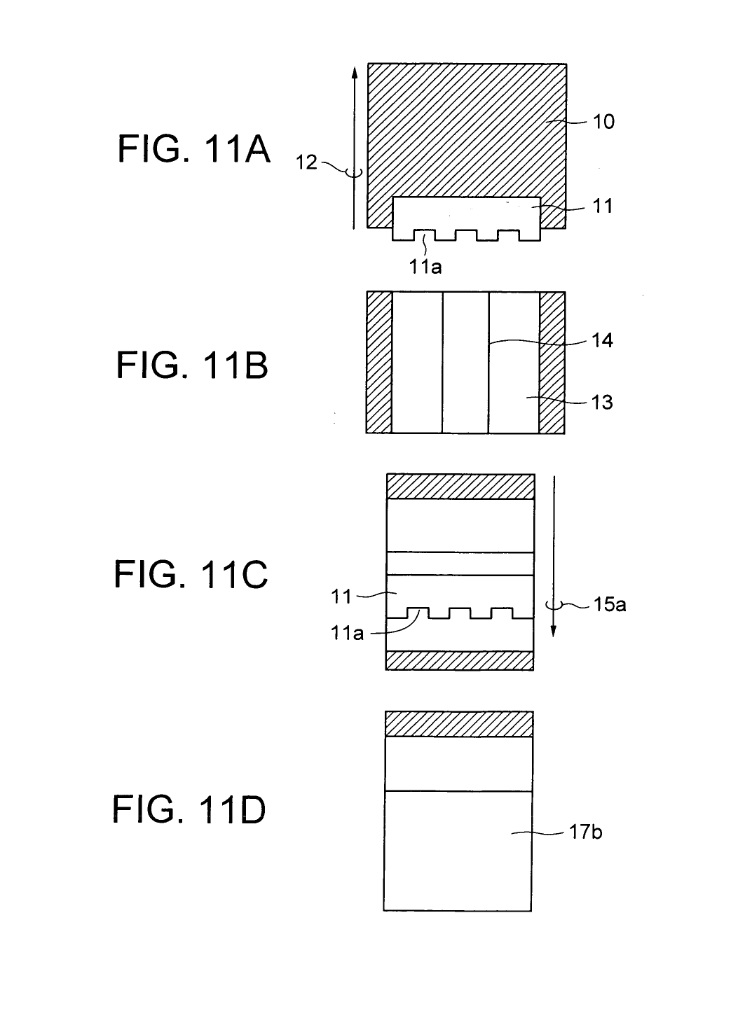

FIG. 11 shows conceptual diagrams of EXAMPLE 2. As shown in FIG. 11A, a beam pattern 11 including a plurality of recessed patterns 11a is scan-irradiated to an amorphous silicon 10 formed on a glass substrate in a first scanning direction 12 (first crystallization step). As shown in FIG. 11B, a plurality of band-shape crystal grains 13 can be formed side by side by the first crystallization. Then, as shown in FIG. 11C, the substrate is rotated by 90 degrees. The beam pattern 11 used in the first crystallization step is scanned-irradiated in a second scanning direction 15a that is rotated by 180 degrees from the first scanning direction 12 (second crystallization) That is, the first scanning direction 12 and the second scanning direction 15a are orthogonal to each other with respect to the substrate. At this time, as shown in FIG. 11C, the side of the beam pattern 11 used in the second crystallization step, which is on the opposite side from the scanning direction 15a, is in a straight-line form. As shown in FIG. 11D, by having the band-shape crystal grains 13 formed in the first crystallization step as the seeds, the grain diameters thereof are expanded in the second scanning direction 15a. Thereby, band-shape crystal grains 17b with the expanded grain diameters can be obtained. In EXAMPLE 2, an effect of shortening the processing time can be expected by using the same beam pattern 11 for the first crystallization step and the second crystallization step. A concrete example thereof will be described hereinafter.

The first crystallization was performed by using the same laser annealing device as that of EXAMPLE 1 and by using a mask in which the recessed pattern was formed periodically as in FIG. 3A. The irradiation condition is shown in Table 3. The irradiation intensity is a value on the substrate. The step width of the laser beam scanning is a distance on the substrate that is scanned by the laser beam during irradiation of each rectangular beam pattern. The aperture part width, the recessed part length, the recessed part width, and the protruded part length in Table 3 are the values on the mask. The beam pattern passed through the mask comes to be in the shape as shown in FIG. 3B on the substrate. The beam size on the substrate becomes one third of the beam size on the mask. That is, the beam width is 6 μm, the beam recessed part length is 1 μm, the beam recessed part width is 3 μm, and the beam protruded part length is 1 μm.

After the first crystallization, the substrate was rotated by 90 degrees and loaded again on the substrate stage. After adjusting the position of the stage in such a manner that the irradiation start position come on the band-shape crystal grain, a beam pattern shaped by using the same mask as that of the first crystallization was scan-irradiated in a direction (second scanning direction) perpendicular to the scanning direction (first scanning direction) of the first crystallization so as to perform the second crystallization. At this time, even though the angle difference between the first scanning direction and the second scanning direction was 90 degrees on the substrate, those were the directions rotated by 180 degrees from each other on the substrate stage. That is, for the beam pattern used in the second crystallization, a side that is on the opposite side from the second scanning direction is in a straight-line form. The irradiation condition is shown in Table 3. The irradiation intensity is a value on the substrate. The step width of the laser beam scanning is a distance on the substrate that is scanned by the laser beam during irradiation of each rectangular beam pattern.

TABLE 3
EXAMPLE 2 (First Crystallization Step)

| | |
|---|---|
| Irradiation intensity (mJ/cm²) | 600 |
| Step width (μm) | 0.2 |
| Aperture part width (μm) | 18 |
| Recessed part length (μm) | 3 |
| Recessed part width (μm) | 9 |
| Protruded part length (μm) | 3 |

TABLE 4
EXAMPLE 2 (Second Crystallization Step)

| | |
|---|---|
| Irradiation intensity (mJ/cm²) | 600 |
| Step width (μm) | 0.2 |

The diameter of the crystal grain obtained in EXAMPLE 2 was almost equal to that of the crystal grain obtained in EXAMPLE 1. Further, the azimuth of the crystal grains obtained in EXAMPLE 2 was almost equal to that of the crystal grains obtained in EXAMPLE 1. Furthermore, the characteristic of the TFT fabricated by using the crystal grains obtained by EXAMPLE 2 as the active layer was almost equal to that of the TFT obtained in EXAMPLE 1. The difference in EXAMPLE 2 with respect to EXAMPLE 1 was that the mask used for shaping the beam in the second crystallization was the same mask as that of the first crystallization. With this, it becomes unnecessary to change the mask, thereby making it possible to reduce the processing time.

### EXAMPLE 3

The first crystallization was performed by using the same laser annealing device as that of EXAMPLE 1 and by using a mask in which the recessed pattern was formed periodically as in FIG. 3A. The irradiation condition is shown in Table 5. The irradiation intensity is a value on the substrate. The step width of the laser beam scanning is a distance on the substrate that is scanned by the laser beam during irradiation of each rectangular beam pattern. The aperture part width, the recessed part length, the recessed part width, and the protruded part length in Table 5 are the values on the mask. The beam passed through the mask comes to be in the shape as shown in FIG. 3B on the substrate. The beam size on the substrate becomes one third of the beam size on the mask. That is, the beam width is 6 μm, the beam recessed part length is 1 μm, the beam recessed part width is 3 μm, and the beam protruded part length is 1 μm.

After the first crystallization, the substrate was rotated by 90 degrees and loaded again on the substrate stage. After adjusting the position of the stage in such a manner that the irradiation start position come on the band-shape crystal grain, a beam pattern shaped by using a rectangular mask as shown in FIG. 5A was scan-irradiated in a direction (second scanning direction) perpendicular to the scanning direction (first scanning direction) of the first crystallization so as to perform the second crystallization. At this time, even though there was an angle difference of 90 degrees between the first scanning direction and the second scanning direction on the substrate, those were the same direction on the substrate stage.

The irradiation condition of the second crystallization is shown in Table 6. The step width of the laser beam scanning is a distance on the substrate that is scanned by the laser beam during irradiation of each rectangular beam pattern. The aperture part width in Table 6 is the value on the mask. The beam size on the substrate becomes one third of the beam size on the mask. That is, the beam width is 3.3 μm.

In the first crystallization, almost the entire substrate was irradiated. Further, in the second crystallization, the scanning distance of one-time scan-irradiation area was set as 20 μm. This is because a large number of crystal grains are generated with the second crystallization from the scanning distance of about 20 μm. Note here that the scan-irradiation area means a continuous area within a beam-irradiated region.

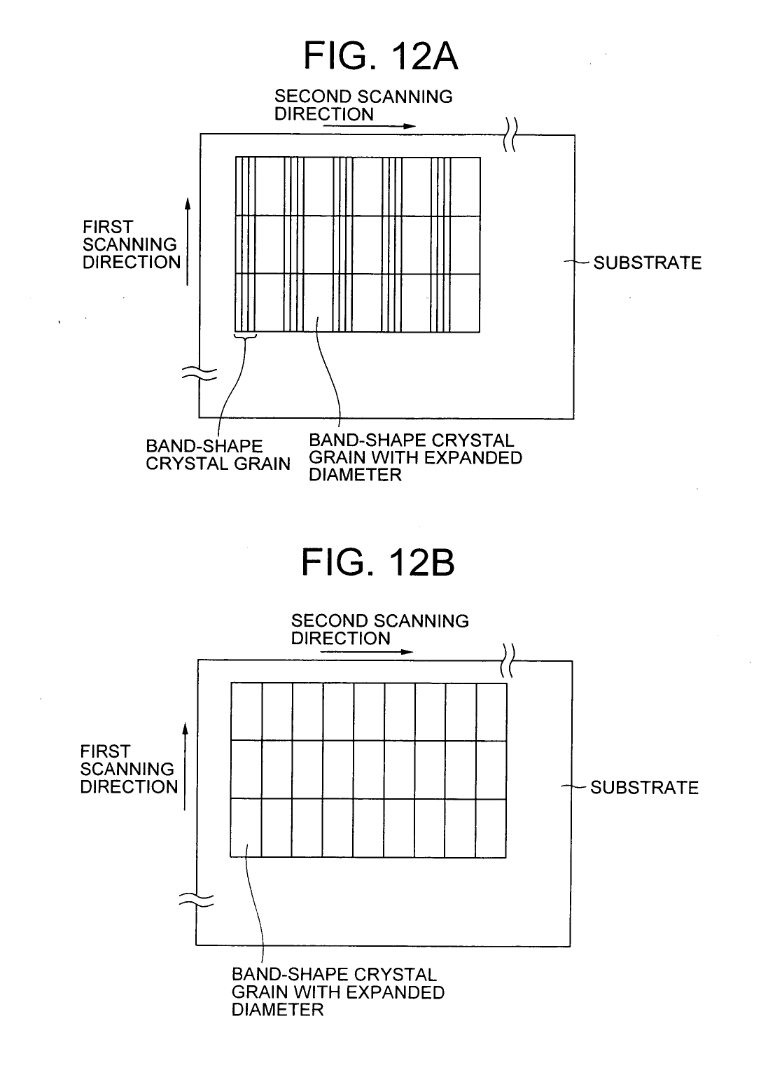

As shown in FIG. 12A, a plurality of scan-irradiation areas were formed by the second crystallization with a scan-irradiation interval of 30 μm in the second scanning direction. Note here that the scan-irradiation interval means the distance between the scanning start positions of the neighboring scan-irradiation areas. With this, it can be expected to form the band-shape crystal grains with the expanded grain diameters efficiently in terms of time and to form those efficiently within the substrate plane. The scanning distance may be set as 50 μm or less, and more preferably as 20 μm or less. Further, it is not necessary for the intervals between the plurality of irradiation areas to be constant, and the interval may be smaller or larger than 30 μm. Furthermore, it is not essential to irradiate the entire surface of the substrate in the first crystallization. Considering the efficiency of the processing, only the positions that require having the seed crystals may be irradiated.

TABLE 5
EXAMPLE 3 (First Crystallization Step)

| | |
|---|---|
| Irradiation intensity (mJ/cm²) | 600 |
| Step width (μm) | 0.2 |
| Aperture part width (μm) | 18 |
| Recessed part length (μm) | 3 |
| Recessed part width (μm) | 9 |
| Protruded part length (μm) | 3 |

TABLE 6
EXAMPLE 3 (Second Crystallization Step)

| | |
|---|---|
| Irradiation intensity (mJ/cm²) | 600 |
| Step width (μm) | 0.2 |
| Aperture part width (μm) | 9.9 |

The diameter of the crystal grain obtained in EXAMPLE 3 was almost equal to that of the crystal grain obtained in EXAMPLE 1. Further, the azimuth of the crystal grains obtained in EXAMPLE 3 was almost equal to that of the crystal grains obtained in EXAMPLE 1. Furthermore, the characteristic of the TFT fabricated by using the crystal grains obtained by EXAMPLE 3 as the active layer was almost equal to that of the TFT obtained in EXAMPLE 1. It was a feature of EXAMPLE 3 that the scanning distance was set as 20 μm, and a plurality of irradiation areas were provided within the substrate plane. With the above, it was able to form the band-shape crystal grains with the expanded grain diameters within the substrate plane efficiently. In EXAMPLE 3, the scanning distance was set as 20 μm. However, it is known that the scanning distance set for expanding the size of the crystal grain diameter in the second crystallization varies depending on the type of the laser, the irradiation intensity, the step width, the film thickness of the silicon film, the film structure of the undercoating of the silicon film, the forming method of the amorphous silicon, the washing condition of the substrate performed right before the laser annealing, etc. Thus, the scanning distance may be designed as appropriate in accordance with those conditions.

### EXAMPLE 4

The first crystallization was performed by using the same laser annealing device as that of EXAMPLE 1 and by using a mask in which the recessed pattern is formed periodically as in FIG. 3A. The irradiation condition is shown in Table 7. The irradiation intensity is a value on the substrate. The step width of the laser beam scanning is a distance on the substrate that is scanned by the laser beam during irradiation of each rectangular beam pattern. The aperture part width, the recessed part length, the recessed part width, and the protruded part length in Table 7 are the values on the mask. The beam passed through the mask comes to be in the shape as shown in FIG. 3B on the substrate. The beam size on the substrate becomes one third of the beam size on the mask. That is, the beam width is 6 μm, the beam recessed part length is 1 μm, the beam recessed part width is 3 μm, and the beam protruded part length is 1 μm.

After the first crystallization, the substrate was rotated by 90 degrees and loaded again on the substrate stage. After adjusting the position of the stage in such a manner that the irradiation start position come on the band-shape crystal grain, a beam shaped by using a rectangular mask as shown in FIG. 5A was scan-irradiated in a direction (second scanning direction) perpendicular to the scanning direction (first scanning direction) of the first crystallization so as to perform the second crystallization. At this time, even though there was an angle difference of 90 degrees between the first scanning direction and the second scanning direction on the substrate, those were the same direction on the substrate stage.

The irradiation condition of the second crystallization is shown in Table 8. The step width of the laser beam scanning is a distance on the substrate that is scanned by the laser beam during irradiation of each rectangular beam pattern. The aperture part width in Table 8 is the value on the mask. The beam size on the substrate becomes one third of the beam size on the mask. That is, the beam width is 3.3 μm.

In the first crystallization, almost the entire substrate was irradiated. Further, in the second crystallization, the scanning distance of one-time scan-irradiation area was set as 20 μm. This is because a large number of crystal grains are generated by the second crystallization from the scanning distance of about 20 μm. Note here that the scan-irradiation area means a continuous area within a beam-irradiated region. As shown in FIG. 12A, a plurality of scan-irradiation areas were formed by the second crystallization with a scan-irradiation interval of 30 μm in the second scanning direction. Note here that the scan-irradiation interval means the distance between the scanning start positions of the neighboring scan-irradiation areas. With this, as shown in FIG. 12B, it is possible to form the band-shape crystal grains with the expanded grain diameters all over the substrate plane.

The scanning distance may be set as 50 μm or less, and more preferably as 20 μm or less. Further, it is not necessary for the intervals between the plurality of irradiation areas to be constant, and the interval may be smaller or larger than 30 μm. Furthermore, it is not essential to irradiate the entire surface of the substrate in the first crystallization. Considering the efficiency of the processing, only the positions that require having the seed crystals may be irradiated.

TABLE 7
EXAMPLE 4 (First Crystallization Step)

| | |
|---|---|
| Irradiation intensity (mJ/cm²) | 600 |
| Step width (μm) | 0.2 |
| Aperture part width (μm) | 18 |
| Recessed part length (μm) | 3 |
| Recessed part width (μm) | 9 |
| Protruded part length (μm) | 3 |

TABLE 8
EXAMPLE 4 (Second Crystallization Step)

| | |
|---|---|
| Irradiation intensity (mJ/cm²) | 600 |
| Step width (μm) | 0.2 |
| Aperture part width (μm) | 9.9 |

The diameter of the crystal grain obtained in EXAMPLE 4 was almost equal to that of the crystal grain obtained in EXAMPLE 1. Further, the azimuth of the crystal grains obtained in EXAMPLE 4 was almost equal to that of the crystal grains obtained in EXAMPLE 1. Furthermore, the characteristic of the TFT fabricated by using the crystal grains obtained by EXAMPLE 4 as the active layer was almost equal to that of the TFT obtained in EXAMPLE 1. It was a feature of EXAMPLE 4 that the irradiation interval was set as equal to or less than the scanning distance in the second crystallization, and the band-shape crystal grains with the expanded crystal diameters were formed all over the substrate plane. With the above, it was able to form the band-shape crystal grains with the expanded grain diameters within the substrate plane efficiently. In EXAMPLE 4, the scanning distance was set as 20 μm. However, it is known that the scanning distance set for expanding the crystal grain diameter in the second crystallization varies depending on the type of the laser, the irradiation intensity, the step width, the film thickness of the silicon film, the film structure of the undercoating of the silicon film, the forming method of the amorphous silicon, the washing condition of the substrate performed right before the laser annealing, etc. Thus, the scanning distance may be designed as appropriate in accordance with those conditions.

Next, another exemplary embodiment of the invention will be described. A semiconductor thin film manufacturing method according to another exemplary embodiment of the invention includes a first crystallization step which irradiates a beam pattern of a laser beam by scanning it to a semiconductor thin film in a first scanning direction to crystallize the semiconductor thin film, and at least a part of the peripheral edge of the beam pattern on the opposite side of the first scanning direction has a recessed pattern. The semiconductor thin film manufacturing method may include, after the first crystallization step, a second crystallization step which irradiates a beam pattern of a laser beam by scanning it to the semiconductor thin film in a second scanning direction that is different from the first scanning direction to crystallize the semiconductor thin film. In other words, the semiconductor thin film manufacturing method according to another exemplary embodiment of the invention is the semiconductor thin film manufacturing method which irradiates a laser to a semiconductor thin film formed on an insulating substrate to grow the semiconductor thin film, wherein a laser including a beam pattern that includes at least one or more recessed patterns on a side that is opposite from a side on the first scanning direction may be scan-irradiated in the first scanning direction to perform the first crystallization and, thereafter, a laser may be scan-irradiated in the second scanning direction that is different from the first scanning direction to perform the second crystallization.

Therefore, it is possible to grow the crystal grains in the second scanning direction by using the band-shape crystal grains formed by the first crystallization step as the seeds. That is, by changing the angles of the first scanning direction and the second scanning direction, it becomes possible to expand the grain diameters of the crystal grains formed in the first crystallization step (fabrication of the band-shape crystal grains with the expanded diameters). Further, providing at least one or more recessed patterns in the first crystallization step, the area of the crystal grain to be the seed can be expanded in the second crystallization step. This provides such an effect that it is unnecessary for the laser annealing device to have a sophisticated alignment mechanism.

The angle difference between the first scanning direction and the second scanning direction may be set as 90 degrees. On this condition, the first scanning direction and the second scanning direction are orthogonal to each other. Therefore, it provides a situation where the opposite side from the second scanning direction of the peripheral edge of the beam pattern in the second crystallization step hardly crosses with the crystal grain boundaries of the band-shape crystal grains formed in the first crystallization. As a result, it is possible to expand the crystal grain diameter in the first scanning direction to the maximum, and to prevent generation of random crystal grain boundaries.

The peripheral edge of the beam pattern in the second crystallization step, which is on the opposite side of the second scanning direction, maybe in a straight-line form. With this, the opposite side of the second scanning direction of the peripheral edge of the beam pattern in the second crystallization step hardly crosses with the crystal grain boundaries of the band-shape crystal grains formed by the first crystallization step. Therefore, it is possible to expand the crystal grain diameter in the first scanning direction to the maximum.

The beam pattern of the first crystallization step and the beam pattern of the second crystallization step may have the same shape. With this, it becomes unnecessary to change the mask for shaping the beam in the first crystallization step and in the second crystallization step. Therefore, the processing time can be shortened.

Further, in the second crystallization step, the beam pattern is scanned in the second scanning direction for performing intermittent irradiation so as to form a plurality of irradiation areas in the second scanning direction of the semiconductor thin film by the beam pattern. Note here that the “irradiation area” means a continuous area within a region to which the beam pattern is scanned and irradiated. The crystal grain diameter expanded in the second scanning direction is about 20 μm, for example. Therefore, it is possible to form the band-shape crystal grains with the expanded grain diameters within the substrate plane efficiently by forming at least one or more irradiation areas in the second crystallization step.

The distance of scanning the beam pattern while irradiating the beam pattern when forming one of the irradiation areas may be set as 20 μm or less. The crystal grain diameter expanded in the second scanning direction is about 20 μm, for example. Thus, by setting the scanning distance in one irradiation area as 20 μm or less, it is possible to form the band-shape crystal grains with the expanded grain diameters within the substrate plane efficiently.

Provided that the distance of scanning the beam pattern while irradiating the beam pattern for forming one of the irradiation areas is A, and provided that the interval between the start position for irradiating and that scanning the beam pattern for forming one of the irradiation area and the start position for irradiating and scanning the beam pattern for forming neighboring another irradiation area is B, the relation thereof may satisfy B<A. In other words, in the second crystallization step, the scan-irradiation interval (B) maybe set as smaller than the scanning distance (A). With this, the band-shape crystal grains with expanded grain diameters can be formed all over.

In a semiconductor thin film according to an exemplary embodiment of the invention, the main plane azimuth of the semiconductor thin film may be distributed within a range that has an angle difference of 15 degrees with respect to (100). Here, the main azimuth of the semiconductor thin film may be (100). As the main plane azimuth becomes closer to (100) and the difference becomes smaller, the semiconductor thin film comes to have uniform various characteristics. Further, the semiconductor thin film may be formed on a glass substrate. In this case, it is desirable for the main azimuth of the semiconductor thin film to be distributed within a range that has an angle difference of 15 degrees with respect to (100). Here, the main azimuth of the semiconductor thin film may be (100).

The semiconductor thin film manufactured by the manufacturing method according to the exemplary embodiment of the invention has following characteristics. For the main azimuth of the crystal grains formed in the first or the second crystallization step, the main azimuth of the first scanning direction is distributed within a range that has an angle difference of 15 degrees with respect to <110>. Further, for the main azimuth of the crystal grains formed in the first or the second crystallization step, the main azimuth of the second scanning direction is distributed within a range that has an angle difference of 15 degrees with respect to <110>.

When the main plane azimuth of the crystal grains formed in the first crystallization step is (100), the main azimuth in the second scanning direction in the second crystallization step may be <100>. In that case, the crystal grains having the main plane azimuth of (100) formed in the first crystallization step are grown by the second crystallization step while keeping the main azimuth of the second scanning direction as <110>. Thus, it is possible to control the azimuth of the second scanning direction of the crystal grains as <110> stably, so that the variations in the TFT characteristic within the substrate plane can be suppressed. When the first scanning direction is <110> and the second scanning direction crosses with the first scanning direction at an angle of 90 degrees, the second scanning direction is also <110>. In that case, there are total of four kinds of <110> for the main plane azimuth (100) of the crystal grains, i.e. the first scanning direction, the second scanning direction, and opposite directions of those.

The semiconductor thin film according to the present invention may be used as an active layer under a gate insulating film, and the main plane azimuth of the active layer that is in contact with the gate insulating film may be distributed within a range that has an angle difference of 15 degrees with respect to (100). Preferably, the main plane azimuth of the active layer that is in contact with the gate insulating film may be (100). Further, the main azimuth of a carrier running direction in the active layer may be distributed within a range that has an angle difference of 15 degrees with respect to <110>. Preferably, the main azimuth of the carrier running direction in the active layer maybe <110>. That is, for the TFT according to the exemplary embodiment of the invention, it is desirable for the main plane azimuth of the active layer to be (100) for the surface of the gate insulating film. With this, the variation in the TFT characteristic within the substrate plane can be suppressed. Further, the main azimuth of the carrier running direction in the active layer may be <110>. With this, the variation in the TFT characteristic within the substrate plane can be suppressed.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A semiconductor thin film manufacturing method which crystallizes a semiconductor thin film on a substrate by irradiation of a laser beam, comprising:
shaping an irradiation pattern of the laser beam into a beam pattern including a recessed pattern on one side by letting the laser beam through a mask;
growing crystal grains by having the recessed pattern as a center through scanning the beam pattern in a first scanning direction to grow band-shape crystal grains; and
expanding a crystal grain diameter of the semiconductor thin film by using the band-shape crystal grains as seeds through scanning a beam pattern in a second scanning direction that is different from the first scanning direction.

2. The semiconductor thin film manufacturing method as claimed in claim 1, wherein the beam pattern used for scanning in the first scanning direction is different from the beam pattern used for scanning in the second scanning direction.

3. The semiconductor thin film manufacturing method as claimed in claim 1, wherein the beam pattern comprising the recessed pattern is used as the beam pattern for scanning in the first scanning direction and in the second scanning direction.

4. The semiconductor thin film manufacturing method as claimed in claim 1, wherein an angle difference between the first scanning direction and the second scanning direction is set as 90 degrees.

5. The semiconductor thin film manufacturing method as claimed in claim 1, wherein the beam pattern is scanned in the second scanning direction for performing intermittent irradiation so as to form a plurality of irradiation areas in the second scanning direction by the beam pattern.

6. The semiconductor thin film manufacturing method as claimed in claim 5, wherein a distance of scanning the beam pattern while irradiating the beam pattern for forming one of the irradiation areas is set as 20 μm or less.

7. The semiconductor thin film manufacturing method as claimed in claim 5, wherein, provided that a distance of scanning the beam pattern while irradiating the beam pattern for forming one of the irradiation areas is A, and provided that an interval between a start position for irradiating and scanning the beam pattern for forming one of the irradiation area and a start position for irradiating and scanning the beam pattern for forming neighboring another irradiation area is B, the relation thereof satisfies B<A.

8. A semiconductor thin film that is crystal-grown by irradiation of a laser beam, wherein a main plane azimuth of the semiconductor thin film is distributed within a range that has an angle difference of 15 degrees with respect to (100).

9. The semiconductor thin film as claimed in claim 8, wherein the main plane azimuth of the semiconductor thin film is (100).

10. The semiconductor thin film as claimed in claim 8, wherein the semiconductor thin film is formed on a glass substrate.

11. A thin film transistor including a semiconductor thin film that is grown by irradiation of a laser beam, wherein:
the semiconductor thin film is used as an active layer under a gate insulating film; and a main plane azimuth of the active layer that is in contact with the gate insulating film is distributed within a range that has an angle difference of 15 degrees with respect to (100).

12. The thin film transistor as claimed in claim 11, wherein the main plane azimuth of the active layer that is in contact with the gate insulating film is (100).

13. The thin film transistor as claimed in claim 11, wherein a main azimuth of a carrier running direction in the active layer is distributed within a range that has an angle difference of 15 degrees with respect to <110>.

14. A mask for shaping a beam for growing a semiconductor thin film, comprising, in a transmitting part of the mask, a recessed pattern for shaping the beam into a beam pattern for growing crystal grains of the semiconductor thin film.
